(19) United States
(12) Patent Application Publication
(10) Pub. No.: US 2025/0210331 A1
(43) Pub. Date: Jun. 26, 2025

(54) PLASMA PROCESSING APPARATUS

(71) Applicant: Tokyo Electron Limited, Tokyo (JP)

(72) Inventors: Takumi IMAHASHI, Miyagi (JP); Manabu ISHIKAWA, Miyagi (JP); Yuki KUMAGAI, Miyagi (JP); Hiroki SATO, Miyagi (JP); Yuki KAWADA, Miyagi (JP); Koji YAMAGISHI, Miyagi (JP)

(73) Assignee: Tokyo Electron Limited, Tokyo (JP)

(21) Appl. No.: 19/077,072

(22) Filed: Mar. 12, 2025

Related U.S. Application Data
(63) Continuation of application No. PCT/JP2024/039336, filed on Nov. 6, 2024.

(30) Foreign Application Priority Data
Nov. 17, 2023 (JP) 2023-195824

(51) Int. Cl. H01J 37/32

(52) U.S. Cl. CPC H01J 37/32935; H01J 37/32165; H01J 37/32183; H01J 37/32568; H01J 37/32642; H01J 37/32715; H01J 2237/3343

(57) ABSTRACT

A plasma processing apparatus comprises: a chamber; first and second bias power sources for supplying first and second bias signals; a substrate supporter for supporting a substrate and an edge ring, inside the chamber; an impedance adjustment mechanism; and an electrical path. The substrate supporter includes: first and second regions supporting the substrate and the edge ring, first and second bias electrodes in the first and second regions, and an impedance adjustment electrode provided in the second region and grounded. The impedance adjustment mechanism includes: a first impedance adjustment mechanism controlling the first bias signal. An isolator and the first impedance adjustment mechanism, and the second impedance adjustment mechanism are connected in parallel, and are connected to the impedance adjustment electrode. The electrical path is configured to connect the first bias power source and the second bias power source, to the first bias electrode and the second bias electrode.

### CROSS-REFERENCE TO RELATED APPLICATIONS

This application is a bypass continuation application of International Application No. PCT/JP2024/039336 having an international filing date of Nov. 6, 2024 and designating the United States, the International Application being based upon and claiming the benefit of priority from Japanese Patent Application No. 2023-195824 filed on Nov. 17, 2023, the entire contents of each are incorporated herein by reference.

### TECHNICAL FIELD

The present disclosure relates to a plasma processing apparatus.

### BACKGROUND

Japanese Laid-open Patent Publication No. 2017-130659 discloses that capacitance of a variable capacitor is adjusted to affect an RF amplitude near an edge of a substrate when a plasma sheath is lowered adjacent to an edge ring due to erosion of the edge ring.

### SUMMARY

The present disclosure provides a plasma processing apparatus capable of improving controllability for a plurality of bias RF signals having different frequencies.

According to an exemplary embodiment, a plasma processing apparatus is provided. The plasma processing apparatus comprising: a chamber; a first bias power source configured to supply a first bias signal; a second bias power source configured to supply a second bias signal; a substrate supporter for supporting a substrate and an edge ring; an impedance adjustment mechanism; and an electrical path. The substrate supporter is configured to include: a first region supporting the substrate, a second region provided around the first region and supporting the edge ring, a first bias electrode provided in the first region, a second bias electrode provided in the second region, and an impedance adjustment electrode provided in the second region and grounded. The impedance adjustment mechanism includes: a first impedance adjustment mechanism controlling the first bias signal, an isolator connected between the impedance adjustment electrode and the first impedance adjustment mechanism and blocking the second bias signal, and a second impedance adjustment mechanism controlling the second bias signal. The isolator and the first impedance adjustment mechanism, and the second impedance adjustment mechanism are connected in parallel, and are configured to be connected to the impedance adjustment electrode. The electrical path is configured to connect the first bias power source and the second bias power source, to the first bias electrode and the second bias electrode.

### BRIEF DESCRIPTION OF THE DRAWINGS

FIG. 1 is a diagram illustrating an example of a configuration of a plasma processing apparatus according to a first embodiment of the present disclosure.

FIG. 2 is a diagram illustrating an example of a relationship between consumption and tilting of an edge ring.

FIG. 3 is a diagram illustrating an example of a circuit configuration of an impedance adjustment mechanism according to the first embodiment.

FIG. 4 is a diagram illustrating another example of the circuit configuration of the impedance adjustment mechanism according to the first embodiment.

FIG. 5 is a graph illustrating an example of a relationship between electrostatic capacitance and reactance of a variable capacitor.

FIG. 6 is a graph illustrating an example of the relationship between the electrostatic capacitance and the reactance of the variable capacitor.

FIG. 7 is a graph illustrating an example of influence between a plurality of variable capacitors.

FIG. 8 is a graph illustrating an example of the influence between the plurality of variable capacitors.

FIG. 9 is a diagram illustrating an example of adjustment of the plurality of variable capacitors according to the first embodiment.

FIG. 10 is a diagram illustrating an example of a consumption amount of an edge ring in a reference example.

FIG. 11 is a diagram illustrating an example of a consumption amount of an edge ring in Modification Example 1.

FIG. 12 is a diagram illustrating an example of a relationship between a sheath potential and capacitance of a variable capacitor in Modification Example 1.

FIG. 13 is a diagram illustrating an example of a bias of an etching rate.

FIG. 14 is a diagram illustrating an example of an arrangement of a conductive bar in Modification Example 2.

FIG. 15 is a diagram illustrating an example of an arrangement of a conductive bar in Modification Example 3.

FIG. 16 is a diagram illustrating an example of an arrangement of a conductive bar in Modification Example 4.

FIG. 17 is a diagram illustrating an example of an arrangement of a conductive bar in Modification Example 5.

FIG. 18 is a diagram illustrating an example of a configuration of an electrical path in Modification Example 6.

FIG. 19 is a diagram illustrating an example of a configuration of a plasma processing apparatus according to a second embodiment.

FIG. 20 is a diagram illustrating an example of independent controllability on an edge ring side according to the second embodiment.

### DETAILED DESCRIPTION

Hereinafter, embodiments of a disclosed plasma processing apparatus will be described in detail with reference to the drawings. In addition, a disclosed technology is not limited by the following embodiments.

In the plasma processing apparatus, in some cases, a thickness of a plasma sheath may differ depending on a potential difference between a substrate and an edge ring. For example, when the edge ring is consumed, a height of the plasma sheath above the edge ring may be lowered (resulting in an increase in sheath thickness) in some cases. For this reason, at a peripheral edge portion of the substrate, a direction of an electric field may not be perpendicular to the substrate, causing ion trajectories to tilt. This can lead to tilting (inner tilt) of an etching hole. In this regard, for example, it is considered to independently control a potential on the edge ring side. However, for example, when two bias RF signals having different frequencies are used as a bias power source, the potential at one frequency may be controllable, but the potential at the other frequency may not be controllable in some cases. Therefore, it is expected to improve controllability for a plurality of bias RF signals with different frequencies.

### First Embodiment

### Configuration of Plasma Processing Apparatus 1

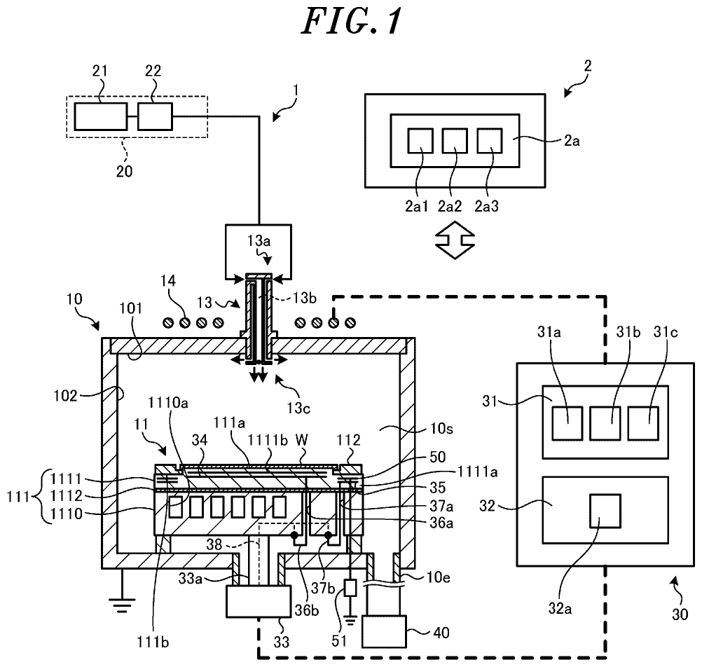

Hereinafter, a configuration example of a plasma processing system will be described. FIG. 1 is a diagram illustrating an example of a configuration of a plasma processing apparatus according to a first embodiment of the present disclosure. The plasma processing system includes an inductively coupled plasma processing apparatus 1 and a controller 2. The inductively coupled plasma processing apparatus 1 includes a plasma processing chamber 10, a gas supply section 20, a power source 30, and an exhaust system 40. The plasma processing chamber 10 includes a dielectric window 101. In addition, the plasma processing apparatus 1 includes a substrate supporter 11, a gas introduction section, and an antenna 14. The substrate supporter 11 is arranged inside the plasma processing chamber 10. The antenna 14 is arranged on the plasma processing chamber 10, or over the plasma processing chamber 10 (i.e., above the dielectric window 101). The plasma processing chamber 10 includes a plasma processing space 10s defined by the dielectric window 101, a side wall 102 of the plasma processing chamber 10, and the substrate supporter 11. The plasma processing chamber 10 includes at least one gas supply port for supplying at least one processing gas to the plasma processing space 10s and at least one gas discharge port for discharging the gas from the plasma processing space. The plasma processing chamber 10 is grounded.

The substrate supporter 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 when viewed in a plan view. The substrate W is arranged on the central region 111a of the main body 111, and the ring assembly 112 is arranged on the annular region 111b of the main body 111 to surround the substrate W on the central region 111a of the main body 111. Therefore, the central region 111a is also referred to as a substrate support surface for supporting the substrate W, and the annular region 111b is also referred to as a ring support surface for supporting the ring assembly 112. In addition, the substrate supporter 11 is an example of a substrate supporter, the central region 111a is an example of a first region, and the annular region 111b is an example of a second region. In addition, in the following description, the central region 111a may be sometimes represented by a substrate support surface 111a, and the annular region 111b may be sometimes represented by a ring support surface 111b.

In one embodiment, the main body 111 includes a base 1110, an electrostatic chuck 1111, and an adhesive layer 1112. The base 1110 includes a conductive member. The conductive member of the base 1110 may function as a portion of an electrical path 38 connected to a first bias electrode 34 and a second bias electrode 35 which will be described later. A power supply line 33a is connected to a bottom portion of the base 1110. In addition, the electrical path 38 also includes the power supply line 33a. The electrostatic chuck 1111 is arranged on the base 1110 through the adhesive layer 1112. The electrostatic chuck 1111 is arranged over the base 1110. The electrostatic chuck 1111 includes a ceramic member 1111a and an electrostatic electrode 1111b arranged inside the ceramic member 1111a. The ceramic member 1111a has the central region 111a. In one embodiment, the ceramic member 1111a also has the annular region 111b. In addition, another member surrounding the electrostatic chuck 1111, such as an annular electrostatic chuck or an annular insulating member, may have the annular region 111b. In this case, the ring assembly 112 may be arranged on the annular electrostatic chuck or the annular insulating member, or may be arranged on both sides of the electrostatic chuck 1111 and the annular insulating member. In addition, at least one RF/DC electrode coupled to a Radio Frequency (RF) power source 31 and/or a Direct Current (DC) power source 32 which will be described later may be arranged inside the ceramic member 1111a. In this case, at least one RF/DC electrode functions as a bias electrode. That is, the first bias electrode 34 and the second bias electrode 35 which will be described later are electrically connected to the RF power source 31 and/or the DC power source 32 through the electrical path 38. In addition, the conductive member of the base 1110 and at least one RF/DC electrode may function as a plurality of bias electrodes. In addition, the electrostatic electrode 1111b may function as a bias electrode, and the first bias electrode 34 may function as an electrostatic electrode. Accordingly, the substrate supporter 11 includes at least one bias electrode.

The ring assembly 112 includes one or a plurality of annular members. In one embodiment, the one or the plurality of annular members includes one or a plurality of edge rings and at least one cover ring. The edge ring is formed of a conductive material or an insulating material, and the cover ring is formed of an insulating material.

In addition, the substrate supporter 11 may include a temperature control module configured to control at least one of the electrostatic chuck 1111, the ring assembly 112, and the substrate W to have a target temperature. The temperature control module may include a heater, a heat transfer medium, a flow path 1110a, or a combination thereof. A heat transfer fluid, such as brine or a gas, flows through the flow path 1110a. In one embodiment, the flow path 1110a is formed inside the base 1110, and one or a plurality of heaters are arranged inside the ceramic member 1111a of the electrostatic chuck 1111. In addition, the substrate supporter 11 may include a heat transfer gas supply section configured to supply a heat transfer gas to a gap between a back surface of the substrate W and the central region 111a.

The electrostatic chuck 1111 is internally provided with an electrostatic electrode 1111b and a first bias electrode 34 arranged in order from the substrate support surface 111a side, in a lower portion of the substrate support surface 111a, and is formed of a dielectric, for example, ceramic. In addition, the electrostatic chuck 1111 is internally provided with an impedance adjustment electrode 50 and a second bias electrode 35, arranged in order from the ring support surface 111b side, in a lower portion of the ring support surface 111b. For example, the first bias electrode 34 is connected to a bottom portion of the base 1110 through a conductor 36b passing through a through-hole 36a of the base 1110. In addition, an insulating sleeve (not illustrated) is provided inside the through-hole 36a, and the base 1110 and the conductor 36b are electrically insulated inside the through-hole 36a. For example, the second bias electrode 35 is connected to a bottom of the base 1110 through a conductor 37b passing through a through-hole 37a of the base 1110. In addition, an insulating sleeve (not illustrated) is provided inside the through-hole 37a, and the base 1110 and the conductor 37b are electrically insulated inside the through-hole 37a.

That is, the first bias electrode 34 and the second bias electrode 35 are connected to a matching circuit 33 which will be described later, through the conductors 36b and 37b, the base 1110, and the power supply line 33a, and the electrical path 38 is formed. In addition, a connection between the first bias electrode 34 and the second bias electrode 35 and the base 1110 is not limited to a conductive member. For example, any method capable of supplying the bias RF signal, such as magnetic resonance, capacitive coupling, and inductive coupling, may be used. That is, the electrical path 38 is configured to connect a bias power source, for example, a first bias RF generator 31b (to be described later), the first bias electrode 34, and the second bias electrode 35. In addition, in the electrical path 38, the first bias RF generator 31b and a second bias RF generator 31c which will be described later are not connected to the base 1110, and the first bias RF generator 31b and the second bias RF generator 31c and the first bias electrode 34 and the second bias electrode 35 may be directly connected. In addition, the second bias electrode 35 has a function of suppressing abnormal discharge of LF1 power supplied from the first bias RF generator 31b (to be described later).

The impedance adjustment electrode 50 is grounded through an impedance adjustment mechanism 51. The impedance adjustment mechanism 51 adjusts the amount of a portion of an RF signal electrical bias supplied from the second bias electrode 35 to flow to a ground side. Since the amount of the RF signal to flow to the ground side is adjusted by the impedance adjustment electrode 50, a potential of the ring assembly 112 is adjusted to be used for controlling a tilt angle and/or adjusting an etching rate. At least one impedance adjustment electrode 50 is provided inside the electrostatic chuck 1111. When a plurality of the impedance adjustment electrodes 50 are provided, for example, two or more are provided in the circumferential direction of the substrate supporter 11, and the impedance adjustment mechanisms 51 are provided to correspond to the number of the impedance adjustment electrodes 50. In addition, two or more impedance adjustment electrodes 50 may be provided in a radial direction of the substrate supporter 11. In addition, two or more impedance adjustment electrodes 50 may be provided in each of the circumferential direction and the radial direction of the substrate supporter 11. In addition, the impedance adjustment electrode 50 is arranged to be parallel to the second bias electrode 35.

The first bias electrode 34 and the second bias electrode 35 are arranged as close as possible to the substrate W and the ring assembly 112, thereby reducing impedance of a capacitor formed by the substrate W, the ring assembly 112, the ceramic of the electrostatic chuck 1111, and the corresponding electrode. As a result, potential differences between the first bias electrode 34 and the substrate W, and between the second bias electrode 35 and the ring assembly 112 are reduced. Similarly, the impedance of the capacitors formed by the first bias electrode 34 and the electrostatic electrode 1111b and by the second bias electrode 35 and the impedance adjustment electrode 50 is also reduced. In addition, the impedance of the capacitors formed by the electrostatic electrode 1111b and the substrate W, and by the impedance adjustment electrode 50 and the ring assembly 112 is also reduced.

In addition, the impedance adjustment electrode may be provided in a lower portion of the substrate support surface 111a, and the impedance adjustment mechanism connected to the impedance adjustment electrode may be provided.

The gas introduction section is configured to introduce at least one processing gas from the gas supply section 20 into the plasma processing space 10s. In one embodiment, the gas introduction section includes a center gas injector (CGI) 13. The center gas injector 13 is arranged above the substrate supporter 11, and is mounted on a center opening portion formed in the dielectric window 101. The center gas injector 13 has at least one gas supply port 13a, at least one gas flow path 13b, and at least one gas introduction port 13c. The processing gas supplied to the gas supply port 13a passes through the gas flow path 13b, and is introduced into the plasma processing space 10s from the gas introduction port 13c. In addition, in addition to or instead of the center gas injector 13, the gas introduction section may include one or a plurality of side gas injectors (SGIs) mounted on one or a plurality of opening portions formed on the side wall 102.

The gas supply section 20 may include at least one gas source 21 and at least one flow rate controller 22. In one embodiment, the gas supply section 20 is configured to supply at least one processing gas to the gas introduction section from each corresponding gas source 21 through each corresponding flow rate controller 22. For example, each flow rate controller 22 may include a mass flow controller or a pressure-controlled flow rate controller. In addition, the gas supply section 20 may include one or a plurality of flow rate modulation devices that modulate or pulse a flow rate of the at least one processing gas.

The power source 30 includes the RF power source 31 coupled to the plasma processing chamber 10 through at least one impedance matching circuit. The RF power source 31 is configured to supply at least one RF signal (RF power) to at least one first bias electrode 34, the second bias electrode 35, and the antenna 14. As a result, plasma is formed from at least one processing gas supplied to the plasma processing space 10s. Therefore, the RF power source 31 may function as at least a portion of a plasma generator configured to generate the plasma from one or a plurality of processing gases in the plasma processing chamber 10. In addition, since the bias RF signal is supplied to at least one first bias electrode 34 and the second bias electrode 35, a bias potential may be generated in the substrate W, and ions in the generated plasma may be attracted to the substrate W.

In one embodiment, the RF power source 31 includes a source RF generator 31a, a first bias RF generator 31b, and a second bias RF generator 31c. The source RF generator 31a is coupled to the antenna 14, and is configured to generate a source RF signal (source RF power) for plasma generation through at least one impedance matching circuit. In one embodiment, the source RF signal has a frequency in a range of 10 MHz to 150 MHz. In one embodiment, the source RF generator 31a may be configured to generate a plurality of source RF signals having different frequencies. The generated one or plurality of source RF signals are supplied to the antenna 14.

The first bias RF generator 31b is coupled to the first bias electrode 34 and the second bias electrode 35 through the matching circuit 33, the power supply line 33a, and the base 1110, and is configured to generate a first bias RF signal (hereinafter also referred to as LF1 power). The generated first bias RF signal is supplied to the first bias electrode 34 and the second bias electrode 35. In one embodiment, the first bias RF signal has a frequency lower than a frequency of the source RF signal. In one embodiment, the first bias RF signal has a frequency in a range of 100 kHz to 5 MHz. The generated first bias RF signal is supplied to at least one of the first bias electrode 34 and the second bias electrode 35.

The second bias RF generator 31c is coupled to the first bias electrode 34 and the second bias electrode 35 through the matching circuit 33, the power supply line 33a, and the base 1110, and is configured to generate a second bias RF signal (hereinafter also referred to as LF2 power). The generated second bias RF signal is supplied to the first bias electrode 34 and the second bias electrode 35. The frequency of the second bias RF signal may be the same as or different from the frequency of the source RF signal. The frequency of the second bias RF signal is higher than the frequency of the first bias RF signal. In one embodiment, the second bias RF signal has a frequency in a range of 1 MHz to 60 MHz. The generated second bias RF signal is supplied to at least one of the first bias electrode 34 and the second bias electrode 35. In addition, in various embodiments, at least one of the source RF signal, the first bias RF signal, and the second bias RF signal may be pulsed. In addition, at least one of the first bias RF signal and the second bias RF signal may have at least two power levels.

The matching circuit 33 is connected to the first bias RF generator 31b, the second bias RF generator 31c, and the substrate supporter 11 (the base 1110). The matching circuit 33 enables the first bias RF signal to be supplied from the first bias RF generator 31b to the substrate supporter 11 through the matching circuit 33. In addition, the matching circuit 33 enables the second bias RF signal to be supplied from the second bias RF generator 31c to the substrate supporter 11 through the matching circuit 33.

In addition, the power source 30 may include a DC power source 32 coupled to the plasma processing chamber 10. The DC power source 32 includes a bias DC generator 32a. In one embodiment, the bias DC generator 32a is connected to at least one of the first bias electrode 34 and the second bias electrode 35, and is configured to generate the bias DC signal. The generated bias DC signal is applied to at least one of the first bias electrode 34 and the second bias electrode 35.

In various embodiments, the bias DC signal may be pulsed. In this case, a sequence of voltage pulses is applied to at least one of the first bias electrode 34 and the second bias electrode 35. The voltage pulse may have a pulse waveform having rectangular, trapezoidal, and triangular shapes, or a combination thereof. In one embodiment, a waveform generator for generating the sequence of the voltage pulses from the DC signal is connected between the bias DC generator 32a and at least one of the first bias electrode 34 and the second bias electrode 35. Accordingly, the bias DC generator 32a and the waveform generator form a voltage pulse generator. The voltage pulse may have a positive polarity, or may have a negative polarity. In addition, the sequence of the voltage pulses may include one or a plurality of positive voltage pulses and one or a plurality of negative voltage pulses within one period. In addition, the bias DC generator 32a may be provided in addition to the RF power source 31, or may be provided instead of at least one of the first bias RF generator 31b and the second bias RF generator 31c. In addition, in the following description, the first bias signal may include the first bias RF signal and/or the bias DC signal, and the second bias signal may include the second bias RF signal and/or the bias DC signal in some cases.

The antenna 14 includes one or a plurality of coils. In one embodiment, the antenna 14 may include an outer coil and an inner coil which are arranged coaxially. In this case, the RF power source 31 may be connected to both of the outer coil and the inner coil, or may be connected to any one of the outer coil and the inner coil. In the former case, the same RF generator may be connected to both of the outer coil and the inner coil, or a separate RF generator may be separately connected to the outer coil and the inner coil.

For example, the exhaust system 40 may be connected to a gas discharge port 10e provided in a bottom portion of the plasma processing chamber 10. The exhaust system 40 may include a pressure regulating valve and a vacuum pump. The pressure inside the plasma processing space 10s is regulated by the pressure regulating valve. The vacuum pump may include a turbomolecular pump, a dry pump, or a combination thereof.

The controller 2 processes computer-executable instructions for causing the plasma processing apparatus 1 to execute various processing described in the present disclosure. The controller 2 may be configured to control each element of the plasma processing apparatus 1 to execute various processing described herein. In one embodiment, the controller 2 may be partially or entirely included in the plasma processing apparatus 1. The controller 2 may include a processor 2a1, a storage 2a2, and a communication interface 2a3. For example, the controller 2 is implemented by a computer 2a. The processor 2a1 may be configured to perform various control operations by reading a program from the storage 2a2 and executing the read program. The program may be stored in the storage 2a2 in advance, or may be acquired through a medium when necessary. The acquired program is stored in the storage 2a2, is read from the storage 2a2, and is executed by the processor 2a1. The medium may be any of various storage media readable by the computer 2a, or may be a communication line connected to the communication interface 2a3. The processor 2a1 may be a Central Processing Unit (CPU). The storage 2a2 may include a Random Access Memory (RAM), a Read Only Memory (ROM), a Hard Disk Drive (HDD), a Solid State Drive (SSD), or a combination thereof. The communication interface 2a3 may communicate with the plasma processing apparatus 1 through a communication line such as a Local Area Network (LAN).

### Relationship between Consumption and Tilting of Edge Ring

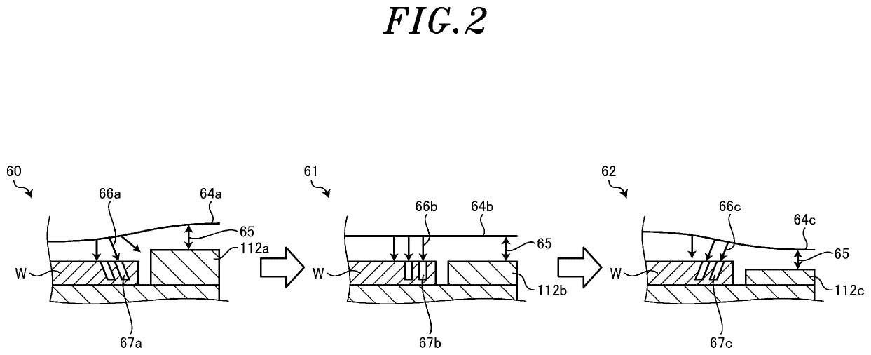

Next, a relationship between consumption and tilting of an edge ring will be described with reference to FIG. 2. FIG. 2 is a diagram illustrating an example of the relationship between consumption and tilting of the edge ring. A state 60 illustrated in FIG. 2 represents a plasma sheath state in a peripheral edge portion of the substrate W in a state where the edge ring is not consumed/eroded. In addition, a state 61 represents a state where the substrate W is processed for a predetermined period of time and the edge ring is progressively consumed. A state 62 represents a state where the substrate W is further processed for a predetermined period of time from the state 61 and the edge ring is further progressively consumed.

In the state 60, a height of an upper surface of the unconsumed edge ring 112a is located at a higher position than an upper surface of the substrate W.

Therefore, a plasma sheath 64a is in a state of floating from the peripheral edge portion of the substrate W to the upper surface of the edge ring 112a. In this case, a distance from the upper surface of the edge ring 112a to the plasma sheath 64a is a gap 65. In this case, in the peripheral edge portion of the substrate W, an electric field direction 66a is tilted outward of the substrate W, and as indicated in a hole 67a, outer tilt occurs in which a bottom portion of the hole is tilted outward of the substrate W. Thereafter, the edge ring 112a is progressively consumed, thereby forming the edge ring 112b indicated in the state 61.

In the state 61, the height of the upper surface of the edge ring 112b is located at approximately the same position as the upper surface of the substrate W. When the bias power applied to the edge ring 112b is the same power as in the state 60, the plasma sheath 64b is located at approximately the same height as the peripheral edge portion of the substrate W. In this case, since the bias power is not changed from the upper surface of the edge ring 112b to the plasma sheath 64b, the gap 65 is maintained as in the state 60. In this case, in the peripheral edge portion of the substrate W, the electric field direction 66b is not tilted, and no tilting occurs as indicated in the hole 67b. Thereafter, the edge ring 112b is progressively consumed, thereby forming the edge ring 112c indicated in the state 62.

In state 62, the height of the upper surface of the edge ring 112c is located at a position lower than the upper surface of the substrate W. Therefore, the plasma sheath 64c is in a state of being lowered from the peripheral edge portion of the substrate W to the upper surface of the edge ring 112c. In this case, since the bias power is not changed from the upper surface of the edge ring 112c to the plasma sheath 64c, the gap 65 is maintained as in the state 60. In this case, in the peripheral edge portion of the substrate W, the electric field direction 66c is tilted inward of the substrate W, and as indicated in the hole 67c, inner tilt occurs in which the bottom portion of the hole is tilted inward of the substrate W. In the present embodiment, the bias power applied to the ring assembly 112 is adjusted in accordance with a consumption amount of the edge ring included in the ring assembly 112. In this manner, the height of the plasma sheath on the upper surface of the substrate W is approximately the same with the height of the plasma sheath on the upper surface of the ring assembly 112. In the present embodiment, the bias power applied to the ring assembly 112 is LF1 power and LF2 power, and may be adjusted by the impedance adjustment mechanism 51 connected to the impedance adjustment electrode 50. In addition, in the following description, the edge ring included in the ring assembly 112 may be simply referred to as the ring assembly 112 in some cases.

### Circuit Configuration of Impedance Adjustment Mechanism

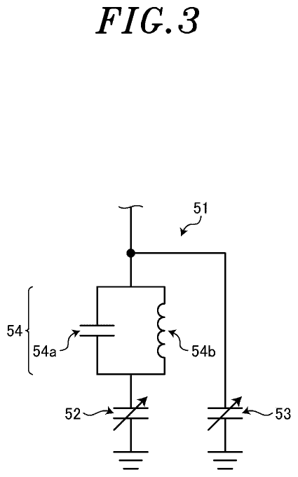

In succession, a circuit configuration of the impedance adjustment mechanism 51 will be described with reference to FIG. 3. FIG. 3 is a diagram illustrating an example of the circuit configuration of the impedance adjustment mechanism in the first embodiment. As illustrated in FIG. 3, the impedance adjustment mechanism 51 includes a first variable capacitor 52 controlling a first bias RF signal, a second variable capacitor 53 controlling a second bias RF signal, and an isolator 54. In addition, in the following description, 400 kHz is used as an example of the frequency of the first bias RF signal, and 12.88 MHz is used as an example of the frequency of the second bias RF signal.

The first variable capacitor 52 has a variable range of electrostatic capacitance of 200 pF to 2,000 pF for example, in order to control power of the first bias RF signal (LF1 power) which is a low-frequency side of 400 kHz. The second variable capacitor 53 has a variable range of electrostatic capacitance of 10 pF to 475 pF, for example, in order to control power of the second bias RF signal (LF2 power) which is a high-frequency side of 12.88 MHz. That is, the first variable capacitor 52 enables control of a high-capacitance range in the impedance adjustment mechanism 51, and the second variable capacitor 53 enables control of a low-capacitance range in the impedance adjustment mechanism 51. In addition, in the following description, the variable capacitor may be referred to as a varicon (a variable capacitor (VC)) in some cases. For example, the first variable capacitor 52 may be represented as a first varicon 52, and the second variable capacitor 53 may be represented as a second varicon 53.

The isolator 54 is connected between the impedance adjustment electrode 50 and the first variable capacitor 52, and blocks the second bias RF signal. That is, the isolator 54 is connected in series to the first variable capacitor 52 at the impedance adjustment electrode 50 side relative to the first variable capacitor 52. In addition, the impedance adjustment mechanism 51 is connected in parallel to the first variable capacitor 52, the isolator 54, and the second variable capacitor 53, and is connected to the impedance adjustment electrode 50.

The isolator 54 includes a capacitor 54a and a coil 54b. The capacitor 54a and the coil 54b form a parallel resonant circuit. The isolator 54 may block the second bias RF signal introduced from the impedance adjustment mechanism 51 side by setting the frequency of the second bias RF signal to 12.88 MHz as the resonant frequency. In addition, the resonant frequency of the parallel resonant circuit of the isolator 54 may be a frequency near the frequency of the second bias RF signal. For example, when the frequency of the second bias RF signal is 12.88 MHz, the resonant frequency of the parallel resonant circuit of the isolator 54 may be 13 MHz. In addition, for example, the isolator 54 may be a low-pass filter configured by using a coil or the like, to allow the first bias RF signal to pass while blocking the second bias RF signal.

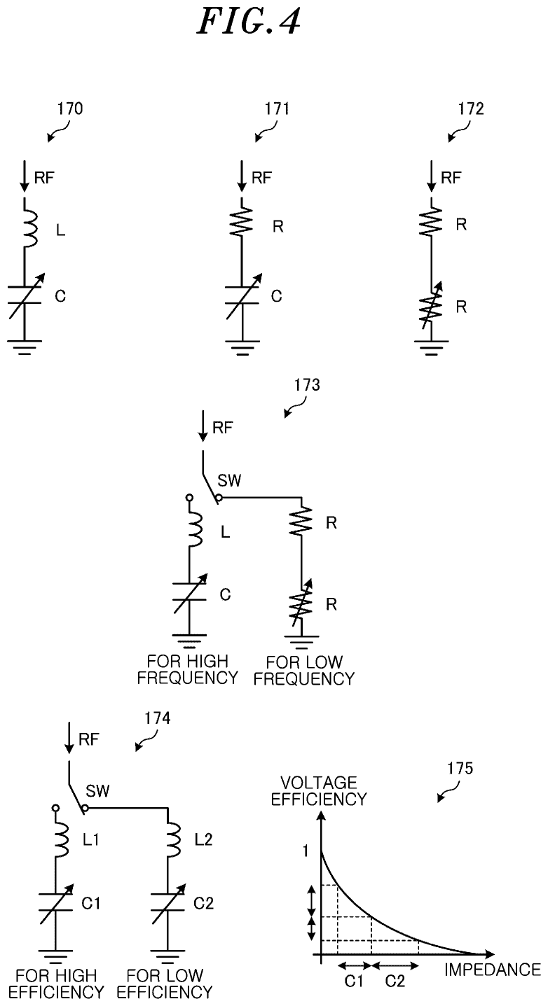

In addition, the first variable capacitor 52 and the second variable capacitor 53 may have circuit configurations including different types of circuit constants. In this case, the first variable capacitor 52 and the second variable capacitor 53 may be respectively represented by the first impedance adjustment mechanism 52 and the second impedance adjustment mechanism 53. A modification example of the circuit configuration in a case of the first impedance adjustment mechanism 52 and the second impedance adjustment mechanism 53 will be described with reference to FIG. 4.

FIG. 4 is a diagram illustrating another example of the circuit configuration of the impedance adjustment mechanism in the first embodiment. As illustrated in FIG. 4, various configurations such as circuits 170 to 174 are considered for the first impedance adjustment mechanism 52 and the second impedance adjustment mechanism 53. The circuit 170 is an LC series circuit using the inductor and the variable capacitor. The circuit 171 is an RC series circuit using the resistor and the variable capacitor. The circuit 172 is an RR series circuit using the resistor and the variable resistor. The circuit 173 is a circuit in which a high-frequency LC series circuit and a low-frequency RR series circuit may be switched by a switch SW. The circuit 174 is a circuit in which a high-efficiency LC series circuit (inductor L1 and the variable capacitor C1) and a low-efficiency LC series circuit (inductor L2 and the variable capacitor C2) may be switched by the switch SW. As illustrated in a graph 175, the circuit 174 is implemented in such a manner that an adjustment range is widened by switching the switch SW. In addition, although not illustrated as an example in FIG. 4, the impedance adjustment mechanisms 52 and 53 may have the circuit configuration using the variable inductor.

In this way, in the first impedance adjustment mechanism 52 and the second impedance adjustment mechanism 53, the variable resistor, the variable capacitor, the variable inductor, and the like may be used regardless of types R, L, and C of the circuit constants to be adjusted. In addition, the first impedance adjustment mechanism 52 and the second impedance adjustment mechanism 53 may combine one or more variable mechanisms (variable resistors, variable capacitors, variable inductors, and the like) in accordance with a frequency, part size, and an adjustment range of the bias RF signal. In addition, since the first impedance adjustment mechanism 52 and the second impedance adjustment mechanism 53 do not need passing of a heater current, the variable resistor or the variable capacitor may be used. In addition, the first impedance adjustment mechanism 52 and the second impedance adjustment mechanism 53 may be configured to include at least one of the variable resistor, the variable capacitor, the variable inductor, and a direct current power source. For example, when the bias RF signal is the high frequency, the impedance between the second bias electrode 35 and the impedance adjustment electrode 50, and the impedance between the impedance adjustment electrode 50 and the ring assembly 112 have small values. Therefore, the potential may be more effectively controlled by using the direct current power source and controlling the potential.

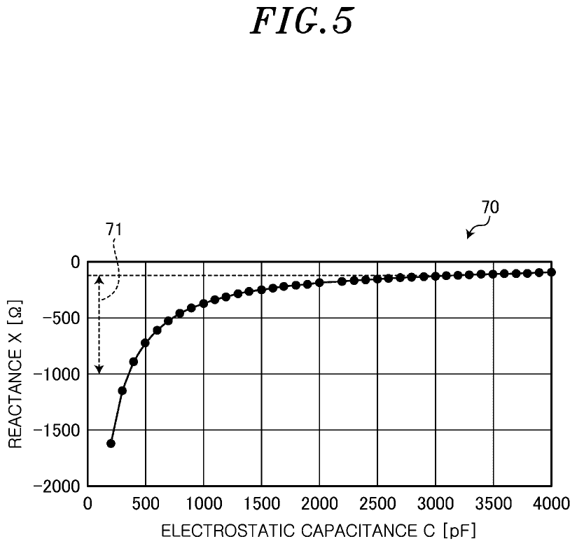

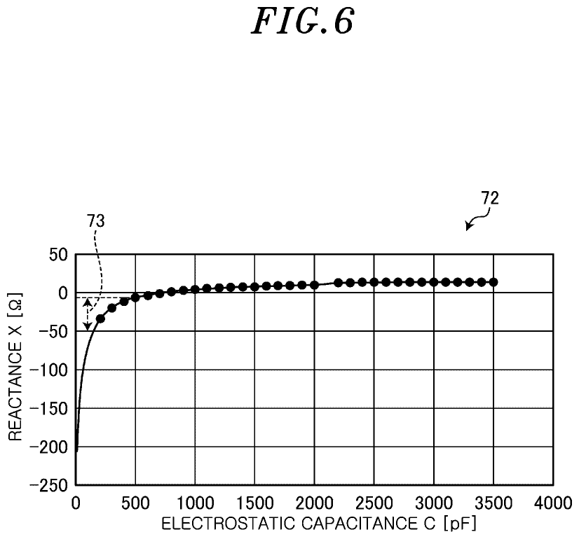

Here, a control range of the first variable capacitor 52 in the first bias RF signal and the second bias RF signal will be described with reference to FIGS. 5 and 6. FIGS. 5 and 6 are graphs illustrating an example of a relationship between electrostatic capacitance and reactance of the variable capacitor. A graph 70 illustrated in FIG. 5 represents a relationship between electrostatic capacitance C and reactance X of the first variable capacitor 52 in the first bias RF signal of 400 kHz. As illustrated in the graph 70, for the first bias RF signal of 400 kHz, a control width 71 of the reactance X may be secured by approximately 900 Ω. The electrostatic capacitance C corresponding to the control width 71 is approximately 350 pF to 3000 pF. In addition, the control width 71 of the reactance X may be widened to approximately 1,500 Ω when a lower limit of the electrostatic capacitance C is widened to approximately 200 pF. Therefore, as described above, a variable range of the first variable capacitor 52 may be set to 200 pF to 2,000 pF.

A graph 72 illustrated in FIG. 6 represents a relationship between the electrostatic capacitance C and the reactance X of the first variable capacitor 52 in the second bias RF signal of 12.88 MHz. As illustrated in the graph 72, for the second bias RF signal 12.88 MHz, the control width 73 of the reactance X is approximately 50 0. The electrostatic capacitance C corresponding to the control width 73 is approximately 150 pF to 500 pF. That is, the first variable capacitor 52 has almost no control width for the second bias RF signal of 12.88 MHz. The reason may be influence of stray capacitance. Therefore, for the second bias RF signal of 12.88 MHz, the first variable capacitor 52 side is blocked by the isolator 54, and the impedance is adjusted by using the second variable capacitor 53.

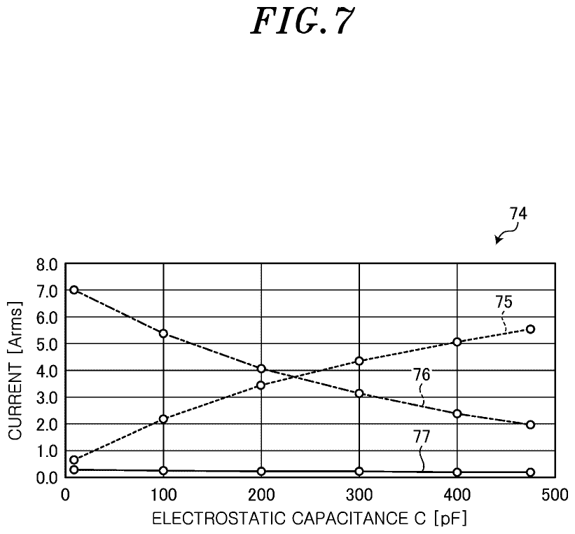

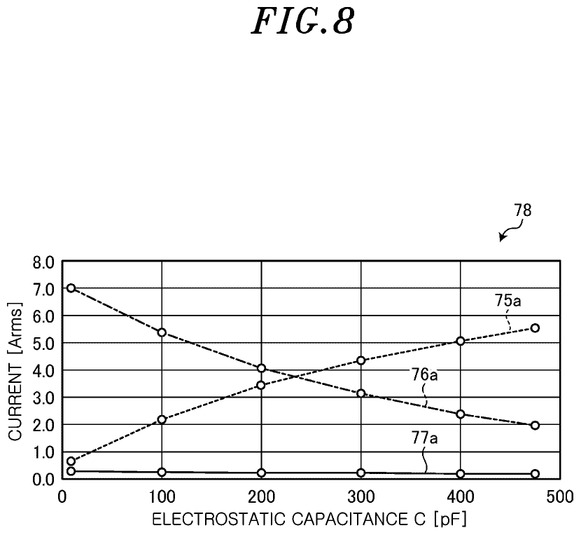

Next, with reference to FIGS. 7 and 8, influence of a change in the electrostatic capacitance of the first variable capacitor 52 on the second variable capacitor 53 when the second bias RF signal of 12.88 MHz is supplied will be described. FIGS. 7 and 8 are graphs illustrating an example of the influence between a plurality of variable capacitors. A graph 74 illustrated in FIG. 7 represents each current of the first variable capacitor 52, the second variable capacitor 53, and the plasma when the second bias RF signal is supplied while the first variable capacitor 52 is set to 200 pF and the electrostatic capacitance C of the second variable capacitor 53 is changed. A graph 75 represents the current on the second variable capacitor 53 side. A graph 76 represents the current of the plasma. A graph 77 represents the current on the first variable capacitor 52 side. As illustrated in the graphs 75 to 77, when the electrostatic capacitance C of the second variable capacitor 53 is changed from 10 pF to 475 pF, the current of the plasma decreases, and the current on the second variable capacitor 53 side increases. On the other hand, the current on the first variable capacitor 52 side hardly flows, and is not changed.

A graph 78 illustrated in FIG. 8 represents each current of the first variable capacitor 52, the second variable capacitor 53, and the plasma when the second bias RF signal is supplied while the first variable capacitor 52 is set to 2000 pF, and the electrostatic capacitance C of the second variable capacitor 53 is changed. A graph 75a represents the current on the second variable capacitor 53 side. A graph 76a represents the current of the plasma. A graph 77a represents the current on the first variable capacitor 52 side. As illustrated in the graphs 75a to 77a, when the electrostatic capacitance C of the second variable capacitor 53 is changed from 10 pF to 475 pF, the current of the plasma decreases and the current on the second variable capacitor 53 side increases. On the other hand, the current on the first variable capacitor 52 side hardly flows, and is not changed. In this way, in the impedance adjustment mechanism 51, it may be understood that the isolator 54 functions and the second bias RF signal is not affected even when the electrostatic capacitance C of the first variable capacitor 52 is changed from 200 pF to 2,000 pF. That is, it may be understood that no current flows into the first variable capacitor 52 side even when the electrostatic capacitance C of the first variable capacitor 52 is changed to high capacitance.

### Adjustment Example of Variable Capacitor

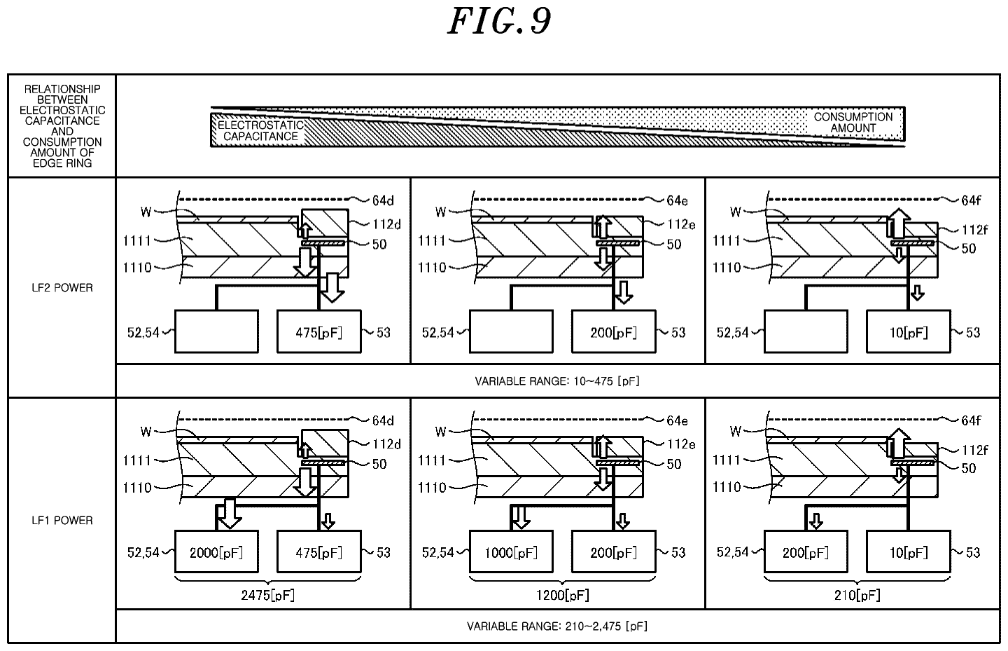

In succession, an adjustment example of the first variable capacitor 52 and the second variable capacitor 53 will be described with reference to FIG. 9. FIG. 9 is a diagram illustrating an example of adjustment of the plurality of variable capacitors in the first embodiment. In FIG. 9, an adjustment example of the electrostatic capacitance of the first variable capacitor 52 and the second variable capacitor 53 in accordance with the consumption amount of the edge ring included in the ring assembly 112 is illustrated from the left side to the right side in the drawing. In addition, in FIG. 9, the first bias electrode 34, the second bias electrode 35, and the electrostatic electrode 1111b are omitted, and flow of the LF1 power and the LF2 power are indicated by white arrows. In addition, the flows of the LF1 power and the LF2 power are relative expressions in FIG. 9, and are not limited thereto. In addition, the LF1 power and the LF2 power may be simultaneously supplied, or may be interchangeably supplied.

First, a case of the unconsumed edge ring 112d on the left side in FIG. 9 will be described. The electrostatic capacitance of the first variable capacitor 52 and the second variable capacitor 53 is adjusted such that the plasma sheath 64d has a constant height from the upper portion of the substrate W and the upper portion of the edge ring 112d. For example, the first variable capacitor 52 is adjusted to 2,000 pF, and the second variable capacitor 53 is adjusted to 475 pF. When the LF2 power of 12.88 MHz is supplied to the impedance adjustment electrode 50, the LF2 power flows more to the impedance adjustment mechanism 51 side than to the edge ring 112d side. That is, the LF2 power flows more to the second variable capacitor 53 side, which is adjusted to 475 pF, than to the edge ring 112d side. In addition, since the LF2 power is blocked by the isolator 54, almost no current flows to the first variable capacitor 52 side. That is, when the LF2 power is supplied to the impedance adjustment electrode 50, the impedance adjustment mechanism 51 appears as a capacitive load having electrostatic capacitance of 475 pF.

When the LF1 power of 400 kHz is supplied to the impedance adjustment electrode 50, the LF1 power flows more to the impedance adjustment mechanism 51 side than to the edge ring 112d side. That is, the LF1 power flows more to the first variable capacitor 52 adjusted to 2,000 pF and the second variable capacitor 53 adjusted to 475 pF than to the edge ring 112d side. In addition, the LF1 power is not blocked by the isolator 54, and flows more to the first variable capacitor 52 side than to the second variable capacitor 53 side. That is, when the LF1 power is supplied to the impedance adjustment electrode 50, the impedance adjustment mechanism 51 appears as a capacitive load having the electrostatic capacitance of 2,475 pF.

Next, a case of the edge ring 112e in which the central portion in FIG. 9 is progressively consumed will be described. The electrostatic capacitance of the first variable capacitor 52 and the second variable capacitor 53 is adjusted such that the plasma sheath 64e has a constant height from the upper portion of the substrate W and the upper portion of the edge ring 112e. For example, the first variable capacitor 52 is adjusted to 1,000 pF, and the second variable capacitor 53 is adjusted to 200 pF. When the LF2 power of 12.88 MHz is supplied to the impedance adjustment electrode 50, the LF2 power flows to the same extent on the edge ring 112e side and the impedance adjustment mechanism 51 side. That is, the LF2 power flows to the same extent on the edge ring 112e side and the second variable capacitor 53 side adjusted to 200 pF. In addition, since the LF2 power is blocked by the isolator 54, almost no current flows to the first variable capacitor 52 side. That is, when the LF2 power is supplied to the impedance adjustment electrode 50, the impedance adjustment mechanism 51 appears as a capacitive load having electrostatic capacitance of 200 pF.

When the LF1 power of 400 kHz is supplied to the impedance adjustment electrode 50, the LF1 power flows to the same extent on the edge ring 112e side and on the impedance adjustment mechanism 51 side. That is, the LF1 power flows to the same extent on the edge ring 112e side and on the first variable capacitor 52 adjusted to 1,000 pF and the second variable capacitor 53 side adjusted to 200 pF. In addition, the LF1 power is not blocked by the isolator 54, and flows more to the first variable capacitor 52 side than to the second variable capacitor 53 side. That is, when the LF1 power is supplied to the impedance adjustment electrode 50, the impedance adjustment mechanism 51 appears as a capacitive load having electrostatic capacitance of 1,200 pF.

In succession, a case of the edge ring 112f in which the right side in FIG. 9 is further progressively consumed will be described. The electrostatic capacitance of the first variable capacitor 52 and the second variable capacitor 53 is adjusted such that the plasma sheath 64f has a constant height from the upper portion of the substrate W and the upper portion of the edge ring 112f. For example, the first variable capacitor 52 is adjusted to 200 pF, and the second variable capacitor 53 is adjusted to 10 pF. When the LF2 power of 12.88 MHz is supplied to the impedance adjustment electrode 50, the LF2 power flows more to the edge ring 112f side than to the impedance adjustment mechanism 51 side. That is, the LF2 power flows more to the edge ring 112f side than to the second variable capacitor 53 side adjusted to 10 pF. In addition, since the LF2 power is blocked by the isolator 54, almost no current flows to the first variable capacitor 52 side. That is, when the LF2 power is supplied to the impedance adjustment electrode 50, the impedance adjustment mechanism 51 appears as a capacitive load having electrostatic capacitance of 10 pF.

When the LF1 power of 400 kHz is supplied to the impedance adjustment electrode 50, the LF1 power flows more to the edge ring 112f side than to the impedance adjustment mechanism 51 side. That is, the LF1 power flows more to the edge ring 112f side than to the first variable capacitor 52 adjusted to 200 pF and the second variable capacitor 53 adjusted to 10 pF. In addition, the LF1 power is not blocked by the isolator 54, and flows more to the first variable capacitor 52 side than to the second variable capacitor 53 side. That is, when LF1 power is supplied to the impedance adjustment electrode 50, the impedance adjustment mechanism 51 appears as a capacitive load having electrostatic capacitance of 210 pF.

In this way, in the adjustment example in FIG. 9, for the LF1 power, the variable range of the electrostatic capacitance as the impedance adjustment mechanism 51 is set to 210 pF to 2475 pF. In addition, for the LF2 power, the variable range of the electrostatic capacitance as the impedance adjustment mechanism 51 is set to 10 pF to 475 pF. That is, the plasma processing apparatus 1 of the present embodiment may improve controllability for the plurality of bias RF signals having different frequencies.

### Modification Example 1

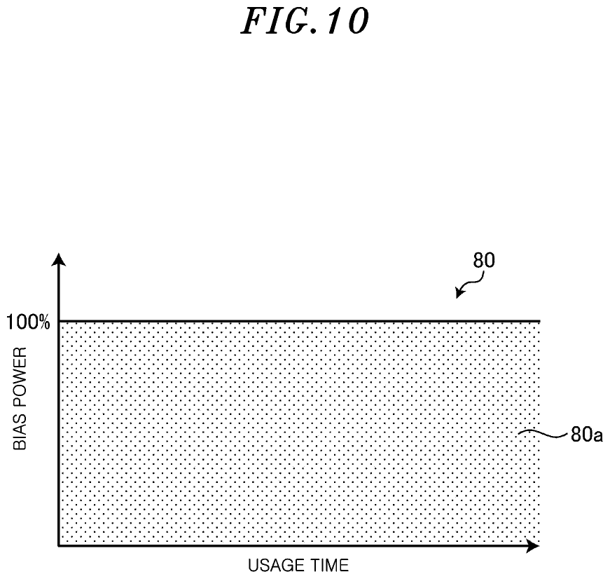

Next, Modification Example 1 of the first embodiment will be described with reference to FIGS. 10 to 12. Modification Example 1 illustrates an example for dealing with a point in which the height of the plasma sheath in the upper portion of the ring assembly 112 tends to be lower than the height of the plasma sheath in the upper portion of the substrate W, by providing the impedance adjustment electrode 50 and the impedance adjustment mechanism 51. In addition, with regard to the impedance adjustment electrode 50, there is also a method of supplying the bias power to the ring assembly 112 from a power source different from the first bias RF generator 31b and the second bias RF generator 31c. However, in this method, the edge ring is easily consumed.

In Modification Example 1, an initial thickness of the edge ring of the ring assembly 112 is made thicker than an initial thickness in the first embodiment. For example, when a state where the impedance adjustment mechanism 51 is not provided is assumed, the initial thickness of the edge ring is set such that the height of the plasma sheath in the upper portion of the ring assembly 112 is higher than the height of the plasma sheath in the upper portion of the substrate W. That is, the initial thickness of the edge ring is set such that that the edge ring shows outer tilt in a state where the impedance adjustment mechanism 51 is not provided. In Modification Example 1, in an initial state, the impedance adjustment mechanism 51 is set to low impedance (e.g., capacitance C is large). Therefore, the height of the plasma sheath in the upper portion of the ring assembly 112 and the height of the plasma sheath in the upper portion of the substrate W are set to be approximately the same. That is, in the initial state, the tilt angle in the peripheral edge portion of the substrate W is brought into a vertical state. Thereafter, in accordance with the consumption amount of the edge ring, the impedance adjustment mechanism 51 is adjusted to high impedance (e.g., capacitance C is small). Therefore, the height of the plasma sheath in the upper portion of the ring assembly 112 and the height of the plasma sheath in the upper portion of the substrate W are set to be approximately the same. That is, in accordance with the consumption amount of the edge ring, the impedance adjustment mechanism 51 is adjusted toward higher impedance (i.e., small capacitance C). In this manner, the tilt angle is corrected.

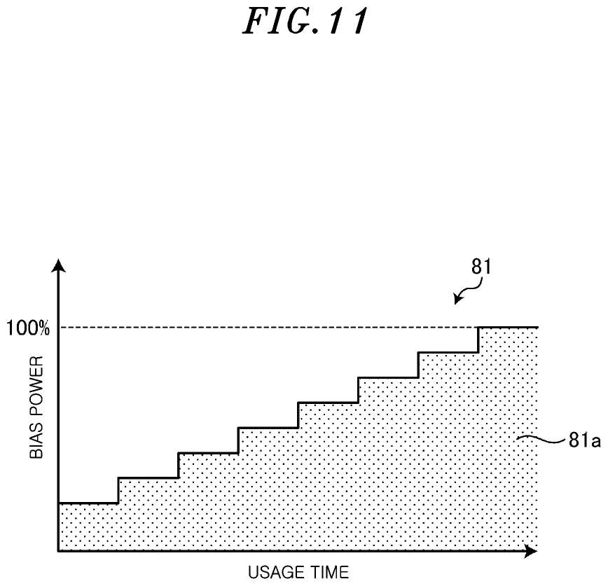

Here, with reference to FIGS. 10 and 11, the lapse of time in the consumption amount of the edge ring and the bias power will be described. FIG. 10 is a diagram illustrating an example of the consumption amount of the edge ring in a reference example. The reference example in FIG. 10 indicates a case where the impedance adjustment mechanism 51 is not provided in the edge ring. A graph 80 illustrated in FIG. 10 represents a relationship between the bias power supplied to the edge ring and a usage time in the reference example. In addition, an area 80a of the graph 80 represents a cumulative consumption amount of the edge ring with respect to the usage time. As illustrated in the graph 80, in the reference example, regardless of the usage time, the constant bias power is supplied to the edge ring as 100% indicated in FIG. 10. Therefore, the consumption amount of the edge ring becomes constant regardless of the usage time.

FIG. 11 is a diagram illustrating an example of the consumption amount of the edge ring in Modification Example 1. Modification Example 1 in FIG. 11 indicates a case where the impedance adjustment mechanism 51 is gradually adjusted from the low impedance to the high impedance in accordance with the consumption amount of the edge ring (or in accordance with usage time). A graph 81 illustrated in FIG. 11 represents a relationship between the bias power supplied to the edge ring and the usage time in Modification Example 1. In addition, the bias power includes the LF1 power and the LF2 power. In addition, an area 81a of the graph 81 represents the cumulative consumption amount of the edge ring with respect to the usage time. As illustrated in the graph 81, in Modification Example 1, when the consumption amount of the edge ring is small, the impedance adjustment mechanism 51 is adjusted to the low impedance such that the bias power supplied to the edge ring side is reduced. In Modification Example 1, thereafter, the impedance adjustment mechanism 51 is gradually adjusted to the high impedance in accordance with the consumption amount of the edge ring. When the area 80a in the reference example and the area 81a in Modification Example 1 are compared, the area 81a is smaller, and in Modification Example 1, a life span of the edge ring of the ring assembly 112 can be extended.

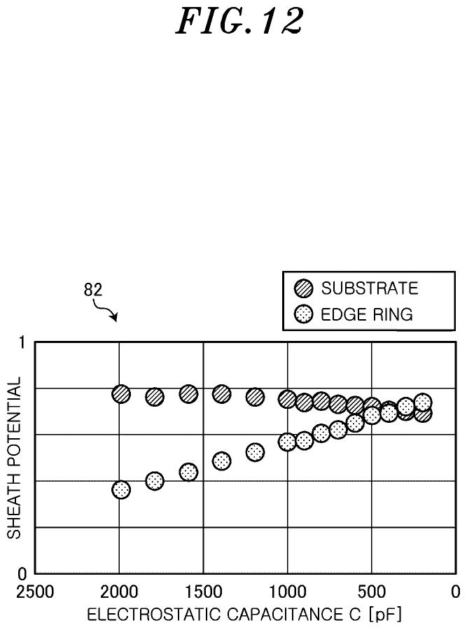

FIG. 12 is a diagram illustrating an example of a relationship between a sheath potential and capacitance of the variable capacitor in Modification Example 1. As illustrated in a graph 82 in FIG. 12, when the impedance adjustment mechanism 51 in Modification Example 1 has low impedance, for example, when the electrostatic capacitance C is 2,000 pF, the sheath potential in the upper portion of the edge ring of the ring assembly 112 becomes smaller than the sheath potential in the upper portion of the substrate W. In addition, the graph 82 represents an absolute value of the sheath potential in a normalized manner within a predetermined range. That is, a gap between the upper surface of the edge ring of the ring assembly 112 and the plasma sheath becomes smaller than a gap between the upper surface of the substrate W and the plasma sheath. In an initial state, the upper surface of the edge ring of the ring assembly 112 in Modification Example 1 becomes higher than the upper surface of the substrate W. Therefore, a difference in the gap between the plasma sheath and the substrate W is compensated for by the thickness of the edge ring of the ring assembly 112. That is, in view of the thickness of the edge ring of the ring assembly 112, the height of the plasma sheath in the upper portion of the ring assembly 112 and the height of the plasma sheath in the upper portion of the substrate W are adjusted to be approximately the same. Thereafter, in accordance with the consumption amount of the edge ring of the ring assembly 112, the impedance adjustment mechanism 51 is adjusted toward higher impedance (impedance capacitance C is small). That is, in accordance with the consumption amount of the edge ring of the ring assembly 112, the height of the plasma sheath in the upper portion of the ring assembly 112 and the height of the plasma sheath in the upper portion of the substrate W are adjusted to be approximately the same.

### Modification Example 2

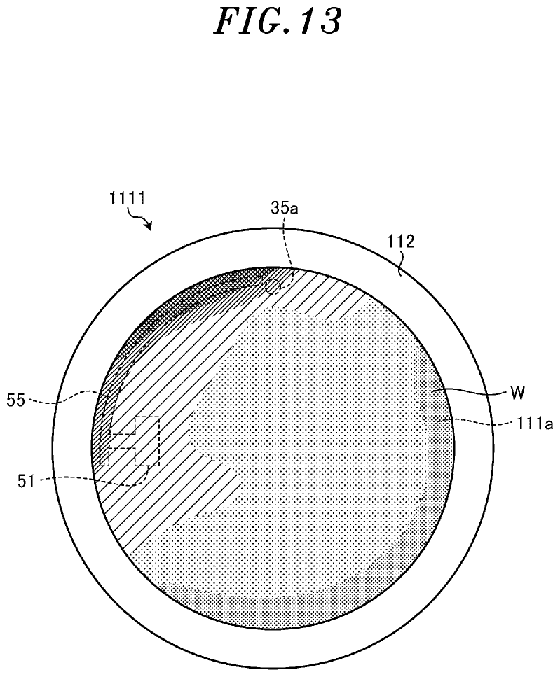

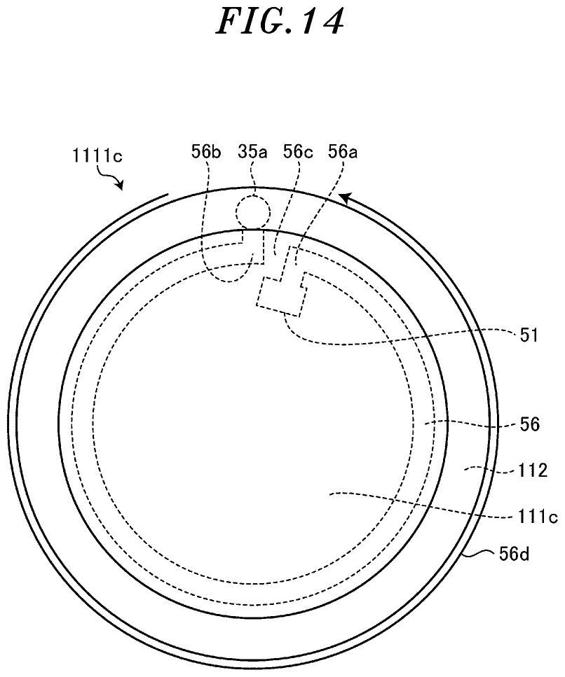

Next, Modification Example 2 of the first embodiment will be described with reference to FIGS. 13 and 14. Modification Example 2 illustrates an example of dealing with a bias in an etching rate due to a layout of the conductive bar connecting the impedance adjustment electrode 50 and the impedance adjustment mechanism 51.

First, the bias in the etching rate will be described with reference to FIG. 13. FIG. 13 is a diagram illustrating an example of the bias in the etching rate. FIG. 13 illustrates an example of the bias in the etching rate of the substrate W when adjustment by the impedance adjustment mechanism 51 is not performed in the electrostatic chuck 1111 when viewed in a plan view. In addition, in FIG. 13, the difference in the etching rate is illustrated by the difference in hatching. As illustrated in FIG. 13, an inlet electrode 35a connected to the second bias electrode 35, the impedance adjustment mechanism 51, and an arc-shaped conductive bar 55 connected to the impedance adjustment mechanism 51 are arranged below the substrate support surface 111a. The inlet electrode 35a forms a portion of the electrical path 38, and is connected to the first bias RF generator 31b and the second bias RF generator 31c. In addition, the conductive bar 55 is arranged along the inner peripheral side of the ring assembly 112 from a connection portion connected to the impedance adjustment mechanism 51, and is connected to the impedance adjustment electrode 50 near the inlet electrode 35a. The other end of the impedance adjustment mechanism 51 is electrically connected and grounded to the outer side of the electrostatic chuck 1111. As illustrated in FIG. 13, there is the bias in the etching rate of the substrate W in a direction of 9 o'clock to 12 o'clock when viewed in a plan view where the impedance adjustment mechanism 51 and the conductive bar 55 are located.

FIG. 14 is a diagram illustrating an example of an arrangement of the conductive bar in Modification Example 2. In an electrostatic chuck 1111c in Modification Example 2 illustrated in FIG. 14, the inlet electrode 35a, the impedance adjustment mechanism 51, and the arc-shaped conductive bar 56 are arranged in a lower portion from the peripheral edge portion of the central region 111c to the annular region 111b of the ring assembly 112. The inlet electrode 35a connected to the second bias electrode 35 forms a portion of the electrical path 38, and is connected to the first bias RF generator 31b and the second bias RF generator 31c. In addition, the conductive bar 56 connected to the impedance adjustment mechanism 51 is arranged over approximately one turn along the inner peripheral side of the ring assembly 112 from a first connection portion 56a connected to the impedance adjustment mechanism 51. The conductive bar 56 is connected to the impedance adjustment electrode 50 in a second connection portion 56b connected to the impedance adjustment electrode 50 near the inlet electrode 35a. That is, the conductive bar 56 is arranged along the inner peripheral side of the second region of the annular region 111b, and includes the first connection portion 56a connected to the impedance adjustment mechanism 51 and the second connection portion 56b connected to the impedance adjustment electrode 50. In addition, in the conductive bar 56, the first connection portion 56a and the second connection portion 56b are adjacent to each other in the circumferential direction through a gap 56c, which is an unconnected portion in the circumferential direction of the first connection portion 56a and the second connection portion 56b. The other end of the impedance adjustment mechanism 51 is electrically connected and grounded to the outside of the electrostatic chuck 1111c. In the conductive bar 56, since the current flows in a direction of an arrow 56d, it is possible to suppress the bias in the etching rate of the substrate W in the circumferential direction which is caused by a magnetic field generated by the current.

### Modification Example 3

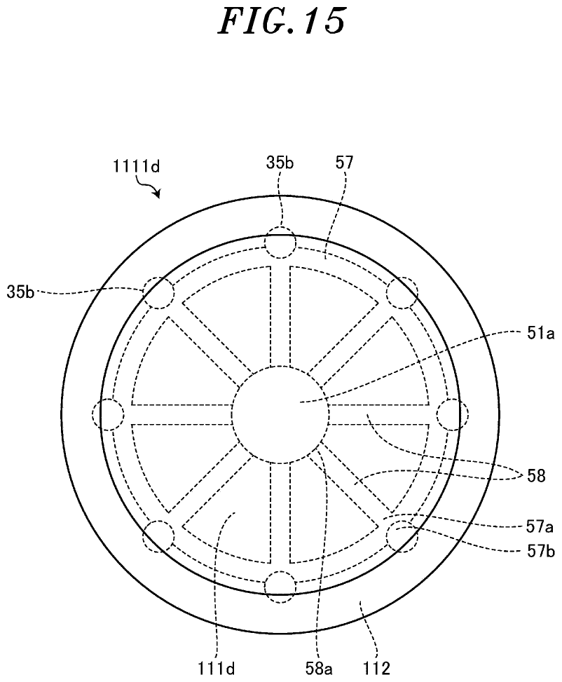

Next, Modification Example 3 of the first embodiment will be described with reference to FIG. 15. As in Modification Example 2, Modification Example 3 illustrates an example of dealing with a bias in the etching rate due to a layout of the conductive bar connecting the impedance adjustment electrode 50 and the impedance adjustment mechanism 51.

FIG. 15 is a diagram illustrating an example of an arrangement of the conductive bar in Modification Example 3. In the electrostatic chuck 1111d in Modification Example 3 illustrated in FIG. 15, a plurality of inlet electrodes 35b connected to the second bias electrode 35 and an impedance adjustment mechanism 51a are arranged in the lower portion of the central region 111d. In addition, in the lower portion of the central region 111d, the arc-shaped first conductive bar 57 connected to the impedance adjustment mechanism 51a and the plurality of second conductive bars 58 arranged from the first conductive bar 57 toward the center of the central region 111d are arranged. Each of the plurality of second conductive bars 58 has a first connection portion 58a connected to the impedance adjustment mechanism 51a. In addition, the other end of the impedance adjustment mechanism 51a is electrically connected and grounded to the outside of the electrostatic chuck 1111d.

The inlet electrode 35b forms a portion of the electrical path 38, and is connected to the first bias RF generator 31b and the second bias RF generator 31c. The first conductive bar 57 is arranged over one turn along the inner peripheral side of the ring assembly 112. The first conductive bar 57 has a plurality of second connection portions 57b connected to the impedance adjustment electrodes 50 in connection portions 57a each connected to the plurality of second conductive bars 58. In addition, for example, the impedance adjustment electrode 50 may be a plurality of impedance adjustment electrodes divided in the circumferential direction. In this case, each of the plurality of impedance adjustment electrodes serves as the second connection portion 57b.

In other words, the electrostatic chuck 1111d includes the first conductive bar 57 arranged in the circumferential direction along the inner peripheral side of the second region of the annular region 111b, and the plurality of second conductive bars 58 arranged from the first conductive bar 57 toward the center of the base 1110 of the substrate supporter 11. In addition, the plurality of second conductive bars 58 each have a first connection portion 58a connected to the impedance adjustment mechanism 51a. In addition, the first conductive bar 57 has the plurality of second connection portions 57b connected to the plurality of impedance adjustment electrodes 50, in the connection portions 57a each connected to the plurality of second conductive bars 58. In this way, the first conductive bar 57 and the plurality of second conductive bars 58 have paths along which the plurality of inlet electrodes 35b connected to the impedance adjustment electrodes 50 are evenly arranged with respect to the impedance adjustment mechanism 51a arranged in the center of the central region 111d. In this manner, the first conductive bar 57 and the plurality of second conductive bars 58 may suppress the bias in the etching rate of the substrate W in the circumferential direction.

### Modification Example 4

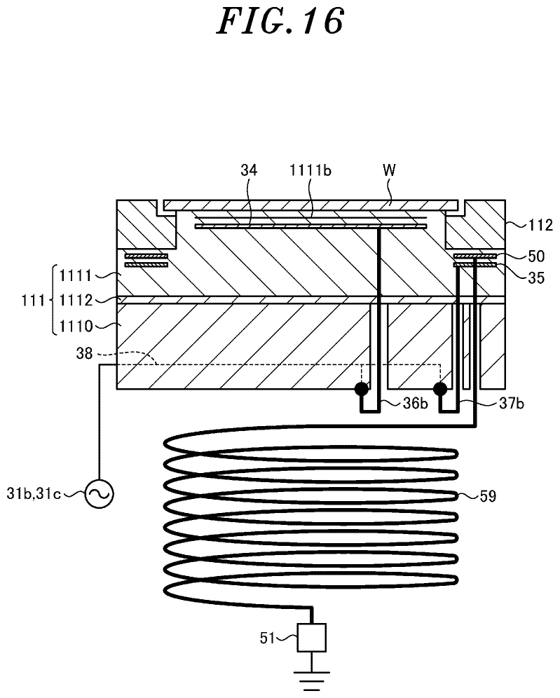

Next, Modification Example 4 of the first embodiment will be described with reference to FIG. 16. As in Modification Example 2, Modification Example 4 illustrates an example of dealing with the bias in the etching rate due to the layout of the conductive bar connecting the impedance adjustment electrode 50 and the impedance adjustment mechanism 51.

FIG. 16 is a diagram illustrating an example of an arrangement of the conductive bar in Modification Example 4. In Modification Example 4 illustrated in FIG. 16, the conductive bar 59 is arranged below the base 1110 of the main body 111. The conductive bar 59 is arranged to have a plurality of turns along the ring assembly 112, that is, the second region of the annular region 111b. That is, for example, a diameter of the conductive bar 59 may be equal to or smaller than a diameter of the electrostatic chuck 1111 and equal to or larger than ½ of a diameter of the central region 111a. One end portion of the conductive bar 59 is connected to the impedance adjustment electrode 50, and the other end portion is connected to the impedance adjustment mechanism 51. In addition, the other end of the impedance adjustment mechanism 51 is electrically connected and grounded to the outside of the plasma processing chamber 10. In this way, the conductive bar 59 has a coil shape along the ring assembly 112, and the current flows in the conductive bar 59. Therefore, the bias in the etching rate of the substrate W in the circumferential direction may be suppressed.

In addition, in Modification Example 4, as in the first embodiment, the LF1 power and the LF2 power which are supplied from the first bias RF generator 31b and the second bias RF generator 31c are supplied to the first bias electrode 34 and the second bias electrode 35 through the electrical path 38. That is, the LF1 power and the LF2 power are supplied to the first bias electrode 34 and the second bias electrode 35 through the electrical path 38 formed by the base 1110 and the conductors 36b and 37b.

### Modification Example 5

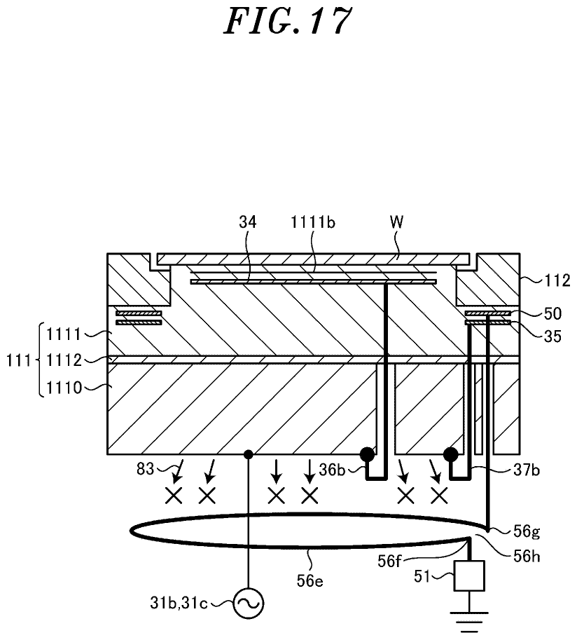

Next, Modification Example 5 of the first embodiment will be described with reference to FIG. 17. Modification Example 5 illustrates an example of dealing with a bias in the etching rate due to the layout of the conductive bar connecting the impedance adjustment electrode 50 and the impedance adjustment mechanism 51, and a power loss due to spatial propagation of the RF power from the base 1110 to the conductive bar.

FIG. 17 is a diagram illustrating an example of an arrangement of the conductive bar in Modification Example 5. As in Modification Example 4, in Modification Example 5 illustrated in FIG. 17, a conductive bar 56e is arranged in the lower portion of the base 1110 of the main body 111. The conductive bar 56e is arranged along the ring assembly 112, that is, the annular region 111b (i.e., the second region). That is, for example, the diameter of the conductive bar 56e may be equal to or smaller than the diameter of the electrostatic chuck 1111, and may be equal to or larger than ½ of the diameter of the central region 111a. In the conductive bar 56e, one end portion 56g is connected to the impedance adjustment electrode 50, and the other end portion 56f is connected to the impedance adjustment mechanism 51. In addition, the other end of the impedance adjustment mechanism 51 is electrically connected and grounded to the outside of the plasma processing chamber 10.

The conductive bar 56e has the same shape as the conductive bar 56 in Modification Example 2, and the end portion 56g and the end portion 56f are adjacent to each other in the circumferential direction through a gap 56h which is an unconnected portion in the circumferential direction of the end portion 56g and the end portion 56f. The conductive bar 56e functions as a split ring resonator. The split ring resonator is configured to have a resonant frequency that resonates with the LF2 power, for example, when the impedance adjustment mechanism 51 adjusts the LF1 power. That is, the resonant frequency of the split ring resonator is the frequency of the second bias RF signal. In addition, the resonant frequency of the split ring resonator may be the frequency of the RF signal (RF power) for plasma generation. In this way, the conductive bar 56e is caused to function as the split ring resonator. A power loss of the RF power may be suppressed by suppressing spatial propagation 83 of the RF power from a HOT section such as the base 1110 to the conductive bar 56e. In addition, the conductive bar 56e has a cylindrical shape along the ring assembly 112 and the current flows in the conductive bar 56e. Therefore, a bias in the etching rate of the substrate W in the circumferential direction may be suppressed.

### Modification Example 6

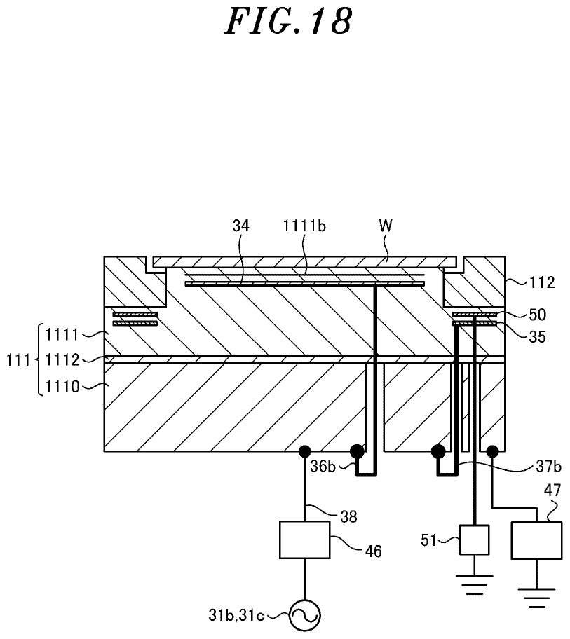

In succession, Modification Example 6 of the first embodiment will be described with reference to FIG. 18. Modification Example 6 represents a case where the power of the electric bias output from the first bias RF generator 31b, the second bias RF generator 31c, and/or the bias DC generator 32a is controlled. In FIG. 18, the first bias RF generator 31b and the second bias RF generator 31c are illustrated as examples.

FIG. 18 is a diagram illustrating an example of a configuration of the electrical path in Modification Example 6. As illustrated in FIG. 18, in the plasma processing apparatus 1 in Modification Example 6, in the electrical path 38, a measurement section 46 is provided between the first bias RF generator 31b, the second bias RF generator 31c, and the base 1110. In addition, in the plasma processing apparatus 1 in Modification Example 6, a high-voltage probe 47 may be provided between the base 1110 and the ground (earth).

For example, the measurement section 46 is a VI probe, and is controlled to measure a voltage and a current of the bias RF signal and/or the bias DC signal output from the first bias RF generator 31b, the second bias RF generator 31c and/or the bias DC generator 32a. That is, the measurement section 46 is controlled to measure the power of the bias RF signal and/or the bias DC signal. The measurement section 46 outputs the measured voltage and current to the controller 2. That is, the measurement section 46 is configured to measure the voltage and the current of the bias RF signal and/or the bias DC signal output from the bias power source.

The high voltage probe 47 is controlled to measure a potential Vpp of the base 1110. In addition, for example, the high voltage probe 47 may be removed during the processing by measuring in advance a relationship between the voltage of the bias RF signal and/or the bias DC signal measured in the measurement section 46 and the potential Vpp of the base 1110 measured by the high voltage probe 47. In this case, the controller 2 may estimate the potential Vpp of the base 1110, based on the relationship between the voltage of the bias RF signal and/or the bias DC signal measured in advance in the measurement section 46 and the potential Vpp of the base 1110 measured in advance.

In Modification Example 6, the controller 2 controls the first bias RF generator 31b, the second bias RF generator 31c and/or the bias DC generator 32a, based on the voltage and the current which are input from the measurement section 46, when the impedance adjustment mechanism 51 is adjusted. That is, the first bias RF generator 31b, the second bias RF generator 31c and/or the bias DC generator 32a perform feedback-control on the power of the bias RF signal and/or the bias DC signal such that the potentials of the first bias electrode 34 and the second bias electrode 35 have preset set values, based on the voltage and the current which are measured in the measurement section 46. Here, for example, the preset set value is a value when the potential Vpp of the base 1110 which is measured by the high-voltage probe 47 becomes a desired potential. In addition, in Modification Example 6, the potentials of the first bias electrode 34 and the second bias electrode 35 may be approximately the same as the potential Vpp of the base 1110 and a potential Vdc of the substrate W and the ring assembly 112.

That is, the plasma processing apparatus 1 further includes the measurement section 46 configured to measure the voltage and the current of the bias RF signal output from at least one of the first bias power source, the first bias RF generator 31b, and the second bias power source, the second bias RF generator 31c. The bias power source is configured to control the power of the bias RF signal such that potentials of the first bias electrode 34 and the second bias electrode 35 have preset set values, based on the voltage and the current which are measured in the measurement section 46, when the impedance adjustment mechanism 51 is adjusted. In addition, the plasma processing apparatus 1 further includes the measurement section 46 configured to measure the voltage and the current of the bias DC signal output from the bias DC generator 32a of at least one of the first bias power source and the second bias power source. The bias power source is configured to control the power of the bias DC signal such that the power supplied to the first bias electrode 34 and the second bias electrode 35 has a preset set value, based on the voltage and the current which are measured in the measurement section 46, when the impedance adjustment mechanism 51 is adjusted.

### Second Embodiment

In the first embodiment described above, the second bias electrode 35 is constantly connected to the base 1110, but a switch may be provided to be turned on/off depending on the frequency of the bias RF signal. An embodiment in this case will be described as a second embodiment. In addition, the plasma processing apparatus in the second embodiment is the same as that in the first embodiment described above, except for the switch provided in the conductor 37b connecting the base 1110 and the second bias electrode 35. Therefore, description of the repeated configurations and operations will be omitted.

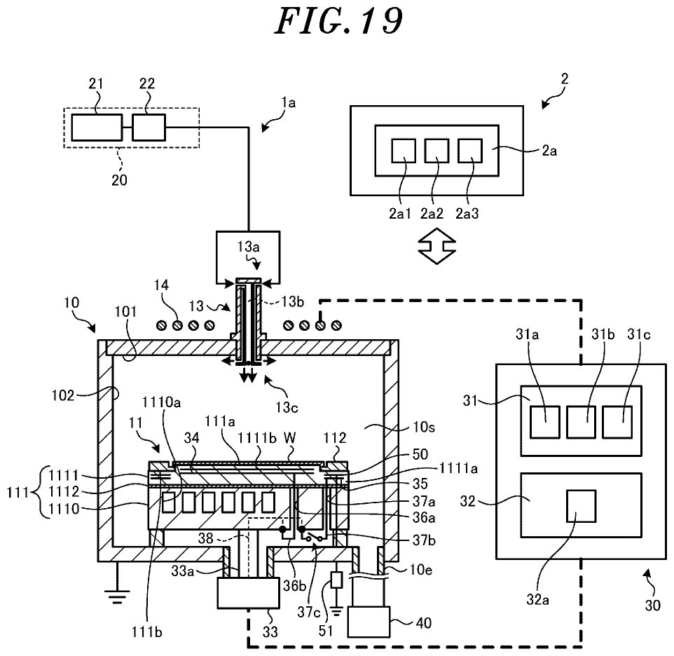

FIG. 19 is a diagram illustrating an example of a configuration of the plasma processing apparatus according to the second embodiment. As illustrated in FIG. 19, a plasma processing apparatus 1a according to the second embodiment includes a switch 37c provided in the conductor 37b according to the first embodiment.

The switch 37c is provided in the conductor 37b connecting the base 1110 and the second bias electrode 35. For example, the switch 37c is provided between the connection portion connected to the base 1110 and an opening portion of the through-hole 37a, in the conductor 37b. The switch 37c is controlled to be turned on when the LF1 power is supplied, and the LF1 power is supplied to the second bias electrode 35. On the other hand, the switch 37c is controlled to be turned off when the LF2 power is supplied, and the LF2 power is not supplied to the second bias electrode 35. That is, the LF1 power is supplied to the first bias electrode 34 and the second bias electrode 35, and the LF2 power is supplied to the first bias electrode 34, but is not supplied to the second bias electrode 35.

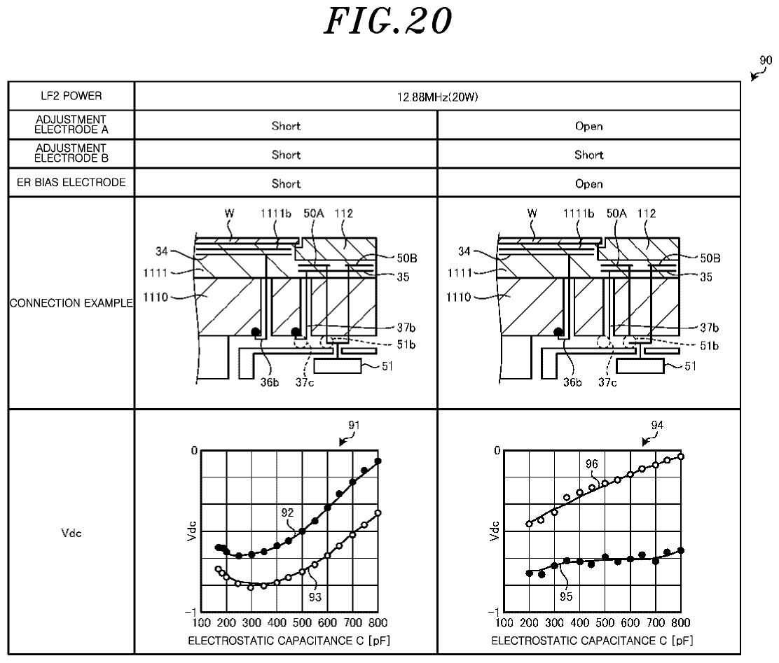

FIG. 20 is a diagram illustrating an example of independent controllability of the edge ring side in the second embodiment. A table 90 illustrated in FIG. 20 shows a summary of the controllability indicated by “Vdc” in the sheath potential table 90 when the switch 37c is turned on/off in a case where the LF2 power of 12.88 MHz and 20 W is supplied. In addition, in the table 90, as illustrated in the connection example, a case where the impedance adjustment electrode 50 includes the adjustment electrode 50A on the inner peripheral side and the adjustment electrode 50B on the outer peripheral side is examined. In addition, the adjustment electrode 50A is provided with the switch 51b between the adjustment electrode 50A and the impedance adjustment mechanism 51. In addition, in the table 90, the adjustment electrodes 50A and 50B are respectively represented as adjustment electrodes A and B, and the second bias electrode 35 is represented as an ER bias electrode. In addition, in the table 90, since no switch is provided for the adjustment electrode 50B, the adjustment electrode 50B is in a state connected to the impedance adjustment mechanism 51, which is indicated as “Short” in table 90. In addition, in the table 90, the first bias electrode 34 and the second bias electrode 35 have the same potential.

In the table 90, when both the switches 37c and 51b are turned on (i.e., in a case where the adjustment electrode A and the ER bias electrode are indicated as “Short” in the table 90), the sheath potential Vdc is illustrated as a graph 91. In the graph 91, the sheath potential in the upper portion of the substrate W is illustrated as a graph 92, and the sheath potential in the upper portion of the edge ring of the ring assembly 112 is illustrated as a graph 93. When the graph 92 and the graph 93 are compared, the shapes of the graphs are the same, and it may be understood that the sheath potential in the upper portion of the substrate W also fluctuates following fluctuations in the sheath potential in the upper portion of the edge ring of the ring assembly 112. The reason is that the impedance between the second bias electrode 35 and the adjustment electrodes 50A and 50B is extremely small when the LF2 power of 12.88 MHz is supplied. That is, when the LF2 power is supplied, it may be understood that there is no independent controllability for the sheath potential in the upper portion of the edge ring of the ring assembly 112 even when the electrostatic capacitance C of the impedance adjustment mechanism 51 is changed to try to adjust the sheath potential in the upper portion of the edge ring of the ring assembly 112. In addition, when both the switch 37c and the switch 51b are turned on and the LF1 power 400 kHz is supplied, the impedance between the second bias electrode 35 and the adjustment electrodes 50A and 50B is high. Therefore, when the LF1 power is supplied, the sheath potential in the upper portion of the edge ring of the ring assembly 112 may be independently controlled. In addition, the impedance adjustment mechanism 51 of the second embodiment may include the variable capacitor. For example, as in the first embodiment, the first variable capacitor 52 and the isolator 54 may be connected in series, and the second variable capacitor 53 may be further connected in parallel. In addition, the impedance adjustment mechanism 51 of the second embodiment may be a single variable capacitor, or may be a combination circuit of the variable capacitor, the resistor, the inductor, and the like.

In the table 90, when both the switches 37c and 51b are turned off (i.e., in a case where the adjustment electrode A and the ER bias electrode are indicated as “Open” in the table 90), the sheath potential Vdc is illustrated in a graph 94. In the graph 94, the sheath potential in the upper portion of the substrate W is illustrated in a graph 95, and the sheath potential in the upper portion of the edge ring of the ring assembly 112 is illustrated in a graph 96. When the graph 95 and the graph 96 are compared, slopes of the graph 95 and the graph 96 are different, and it may be understood that the sheath potential in the upper portion of the edge ring of the ring assembly 112 is controlled independently of the sheath potential in the upper portion of the substrate W. In addition, even when the switch 51b is turned on, the sheath potential in the upper portion of the edge ring of the ring assembly 112 may be similarly controlled independently of the sheath potential in the upper portion of the substrate W. In addition, when a case where both the switch 37c and switch 51b are turned off and the LF1 power of 400 kHz is supplied is examined, the second bias electrode 35 floats on the ring assembly 112 side. Therefore, the LF1 power is supplied from the base 1110. Accordingly, the impedance between the base 1110 and the adjustment electrodes 50A and 50B is high. For this reason, even when the LF1 power is supplied, the sheath potential in the upper portion of the edge ring of the ring assembly 112 may be independently controlled.

In this way, in the plasma processing apparatus 1a of the second embodiment, when the LF1 power of the first bias RF signal is supplied, the switch 37c is controlled to be turned on, and when the LF2 power of the second bias RF signal is supplied, the switch 37c is controlled to be turned off. In this manner, controllability for the plurality of bias RF signals having different frequencies may be improved.

In addition, the above-described embodiments and modification examples may be appropriately combined within the scope in which the embodiments and the modification examples do not contradict each other. For example, the first embodiment and the second embodiment may be combined, or the second embodiment may be combined with Modification Examples 1 to 6 of the first embodiment.

As described above, according to the first embodiment, the plasma processing apparatus 1 includes the chamber (plasma processing chamber 10), the first bias power source (first bias RF generator 31b) configured to supply the first bias signal, the second bias power source (second bias RF generator 31c) configured to supply the second bias signal, the substrate supporter (substrate supporter 11) supporting the substrate W and the edge ring (edge ring assembly 112) inside the chamber, the impedance adjustment mechanism 51, and the electrical path 38. The substrate supporter is configured to have the first region (the central region 111a) supporting the substrate W, the second region (the annular region 111b) provided around the first region and supporting the edge ring, the first bias electrode 34 provided inside the first region, the second bias electrode 35 provided inside the second region, and the impedance adjustment electrode 50 provided and grounded inside the second region. The impedance adjustment mechanism 51 includes the first impedance adjustment mechanism (first variable capacitor 52) controlling the first bias signal, the isolator 54 connected between the impedance adjustment electrode 50 and the first impedance adjustment mechanism and blocking the second bias signal, and the second impedance adjustment mechanism (second variable capacitor 53) controlling the second bias signal. The isolator 54, the first impedance adjustment mechanism, and the second impedance adjustment mechanism are connected in parallel, and are configured to be connected to the impedance adjustment electrode 50. The electrical path 38 is configured to connect the first bias power source and the second bias power source, and the first bias electrode 34 and the second bias electrode 35. As a result, controllability for the plurality of bias signals having different frequencies, for example, the bias RF signal, may be improved.

In addition, according to the second embodiment, the electrical path 38 is provided with the switch 37c between the first bias power source, the second bias power source, and the second bias electrode 35, and the switch 37c is controlled to be turned on when the first bias signal is supplied, and the switch 37c is controlled to be turned off when the second bias signal is supplied. As a result, the sheath potential in the upper portion of the edge ring of the ring assembly 112 may be controlled independently of the sheath potential in the upper portion of the substrate W.

In addition, according to each of the embodiments, the first impedance adjustment mechanism is configured to include at least one of the variable resistor, the variable capacitor, and the variable inductor. In addition, the second impedance adjustment mechanism is configured to include at least one of the variable resistor, the variable capacitor, and the variable inductor. As a result, the potential of the impedance adjustment electrode may be adjusted.

In addition, according to the first embodiment, the frequency of the first bias signal is lower than the frequency of the second bias signal, the first impedance adjustment mechanism is configured to include the first variable capacitor 52, and the second impedance adjustment mechanism is configured to include the second variable capacitor 53. The variable range of the capacitance of the first variable capacitor 52 is larger than the variable range of the capacitance of the second variable capacitor 53. As a result, controllability of the sheath potential on the ring assembly 112 side may be improved for any one of the first bias signal and the second bias signal.

In addition, according to the first embodiment, the isolator 54 includes the resonant circuit in which the resonant frequency is the frequency of the second bias signal. As a result, the second bias signal may be blocked for the first variable capacitor 52.

In addition, according to the second embodiment, the plasma processing apparatus 1a includes the chamber (plasma processing chamber 10), the first bias power source (first bias RF generator 31b) configured to supply the first bias signal, the second bias power source (second bias RF generator 31c) configured to supply the second bias signal, the substrate supporter (substrate supporter 11) supporting the substrate W and the edge ring (edge ring assembly 112) inside the chamber, the impedance adjustment mechanism 51, and the electrical path 38. The substrate supporter is configured to have the first region (central region 111a) supporting the substrate W, the second region (annular region 111b) provided around the first region and supporting the edge ring, the first bias electrode 34 provided inside the first region, the second bias electrode 35 provided inside the second region, and the impedance adjustment electrode 50 provided and grounded inside the second region. The impedance adjustment mechanism 51 is configured to be connected to the impedance adjustment electrode 50. The electrical path 38 is configured to connect the first bias power source and the second bias power source, and the first bias electrode 34 and the second bias electrode 35. The switch 37c is provided between the first bias power source, the second bias power source, and the second bias electrode 35. The switch 37c is controlled to be turned on when the first bias signal is supplied, and is controlled to be turned off when the second bias signal is supplied. As a result, the sheath potential in the upper portion of the edge ring of the ring assembly 112 may be controlled independently of the sheath potential in the upper portion of the substrate W.

In addition, according to the first embodiment, the impedance adjustment mechanism 51 includes the first impedance adjustment mechanism (first variable capacitor 52) controlling the first bias signal, the isolator 54 connected between the impedance adjustment electrode 50 and the first impedance adjustment mechanism and blocking the second bias signal, and the second impedance adjustment mechanism (second variable capacitor 53) controlling the second bias signal. The isolator 54, the first impedance adjustment mechanism, and the second impedance adjustment mechanism are connected in parallel. As a result, controllability for the plurality of bias signals having different frequencies, for example, the bias RF signal, may be improved.

In addition, according to each of the embodiments, the frequency of the first bias signal is lower than the frequency of the second bias signal. As a result, controllability of the potential may be improved for the frequencies of both the first bias signal and the second bias signal, for example, the first bias RF signal and the second bias RF signal.

In addition, according to the first embodiment and Modification Example 1, the impedance adjustment mechanism 51 is adjusted from the low impedance to the high impedance as the consumption amount of the edge ring increases. As a result, controllability for the plurality of bias signals having different frequencies, for example, the bias RF signal, may be improved, and a life span of the edge ring may be extended.

In addition, according to Modification Example 2, the impedance adjustment mechanism 51 is connected to the impedance adjustment electrode 50 through the conductive bar 56. In addition, the conductive bar 56 is arranged along the inner peripheral side of the second region, and has the first connection portion 56a connected to the impedance adjustment mechanism 51, and the second connection portion 56b connected to the impedance adjustment electrode 50. The first connection portion 56a and the second connection portion 56b are adjacent to each other in the circumferential direction through the gap 56c in the unconnected portion in the circumferential direction of the first connection portion 56a and the second connection portion 56b. As a result, a bias in the etching rate of the substrate W in the circumferential direction may be suppressed.

In addition, according to Modification Example 5, the conductive bar 56e is arranged in the lower portion of the base 1110 of the substrate support, and functions as the split ring resonator. As a result, the power loss of the RF power and/or the pulsed DC power may be suppressed, and at the same time, the bias in the etching rate of the substrate W in the circumferential direction may be suppressed.

In addition, according to Modification Example 5, the resonant frequency of the split ring resonator is the frequency of the second bias signal. As a result, the spatial propagation of the RF power and/or the pulsed DC power to the conductive bar 56e may be suppressed.

In addition, according to Modification Example 3, the impedance adjustment mechanism 51a is connected to the plurality of impedance adjustment electrodes 50 through the conductive bars (first conductive bar 57 and second conductive bar 58). The conductive bar includes the first conductive bar 57 arranged in the circumferential direction along the inner peripheral side of the second region, and the plurality of second conductive bars 58 arranged from the first conductive bar 57 toward the center of the base 1110 of the substrate supporter. The plurality of second conductive bars 58 each have the first connection portion 58a connected to the impedance adjustment mechanism 51a. The first conductive bar 57 has the plurality of second connection portions 57b connected to the plurality of impedance adjustment electrodes 50 in the connection portions 57a each connected to the plurality of second conductive bars 58. As a result, a bias in the etching rate of the substrate W in the circumferential direction may be suppressed.

In addition, according to Modification Example 4, the impedance adjustment mechanism 51 is connected to the impedance adjustment electrode 50 through the conductive bar 59, and the conductive bar 59 is arranged along the second region to have a plurality of turns. As a result, a bias in the etching rate of the substrate W in the circumferential direction may be suppressed.

In addition, according to Modification Example 6, the plasma processing apparatus 1 further includes the measurement section 46 configured to measure the voltage and the current of the bias RF signal output from at least one of the first bias power source 31b and the second bias RF generator 31c. The bias power source is configured to control the power of the bias RF signal such that potentials of the first bias electrode 34 and the second bias electrode 35 have preset set values, based on the voltage and the current which are measured in the measurement section 46, when the impedance adjustment mechanism 51 is adjusted. As a result, a change in the etching rate may be suppressed by controlling the bias RF power, when a value of VC is changed.

In addition, according to Modification Example 6, the plasma processing apparatus 1 further includes the measurement section 46 configured to measure the voltage and the current of the bias DC signal output from the bias DC generator 32a of at least one of the first bias power source and the second bias power source. The bias power source is configured to control the power of the bias DC signal such that power supplied to the first bias electrode 34 and the second bias electrode 35 has a preset set value, based on the voltage and the current which are measured in the measurement section 46, when the impedance adjustment mechanism 51 is adjusted. As a result, a change in the etching rate may be suppressed by controlling the bias DC power, when a value of VC is changed.

Each of the embodiments described herein should be considered as illustrative in all respects and not restrictive. Each of the above-described embodiments may be omitted, substituted, or modified in various forms without departing from the scope and the concept of the appended claims.

In addition, in each of the above-described embodiments, the plasma processing apparatuses 1 and 1a which perform processing such as etching on the substrate W by using the inductively coupled plasma as the plasma source have been described as examples. However, the disclosed technology is not limited thereto. When the apparatus performs processing on the substrate W by using the plasma, the plasma source is not limited to the inductively coupled plasma. For example, any plasma source such as capacitively coupled plasma, microwave plasma, or magnetron plasma may be used.

In addition, the present disclosure may also adopt the following configurations.

(1)

A plasma processing apparatus comprising:
a chamber;
a first bias power source configured to supply a first bias signal;
a second bias power source configured to supply a second bias signal;
a substrate supporter for supporting a substrate and an edge ring, inside the chamber;
an impedance adjustment mechanism; and
an electrical path,
wherein the substrate supporter is configured to include:
a first region supporting the substrate,
a second region provided around the first region and supporting the edge ring,
a first bias electrode provided in the first region,
a second bias electrode provided in the second region, and
an impedance adjustment electrode provided in the second region and grounded, and
wherein the impedance adjustment mechanism includes:
a first impedance adjustment mechanism controlling the first bias signal,
an isolator connected between the impedance adjustment electrode and the first impedance adjustment mechanism and blocking the second bias signal, and
a second impedance adjustment mechanism controlling the second bias signal,
wherein the isolator and the first impedance adjustment mechanism, and the second impedance adjustment mechanism are connected in parallel, and are configured to be connected to the impedance adjustment electrode, and
the electrical path is configured to connect the first bias power source and the second bias power source, to the first bias electrode and the second bias electrode.
   (2)

The plasma processing apparatus of (1), wherein the electrical path is provided with a switch between the first bias power source and the second bias power source, and the second bias electrode,
the switch is controlled to be turned on when the first bias signal is supplied, and the switch is controlled to be turned off when the second bias signal is supplied.
   (3)

The plasma processing apparatus of (1) or (2), wherein the first impedance adjustment mechanism is configured to include at least one of a variable resistor, a variable capacitor, and a variable inductor, and
the second impedance adjustment mechanism is configured to include at least one of the variable resistor, the variable capacitor, and the variable inductor.
   (4)

The plasma processing apparatus of (3), wherein a frequency of the first bias signal is lower than a frequency of the second bias signal,
the first impedance adjustment mechanism is configured to include a first variable capacitor,
the second impedance adjustment mechanism is configured to include a second variable capacitor, and
a variable range of capacitance of the first variable capacitor is larger than a variable range of capacitance of the second variable capacitor.
   (5)

The plasma processing apparatus of any one of (1) to (4), wherein the isolator includes a resonant circuit having a resonant frequency that is a frequency of the second bias signal.

(6)

A plasma processing apparatus comprising:
a chamber;
a first bias power source configured to supply a first bias signal;
a second bias power source configured to supply a second bias signal;
a substrate supporter for supporting a substrate and an edge ring, inside the chamber;
an impedance adjustment mechanism; and
an electrical path,
wherein the substrate supporter is configured to include:
a first region supporting the substrate,
a second region provided around the first region and supporting the edge ring,
a first bias electrode provided in the first region,
a second bias electrode provided in the second region, and
an impedance adjustment electrode provided in the second region and grounded, and
wherein the impedance adjustment mechanism is configured to be connected to the impedance adjustment electrode, and
the electrical path is configured to connect the first bias power source and the second bias power source, to the first bias electrode and the second bias electrode, and
a switch is provided between the first bias power source and the second bias power source, and the second bias electrode, and
the switch is controlled to be turned on when the first bias signal is supplied, and the switch is controlled to be turned off when the second bias signal is supplied.
   (7)

The plasma processing apparatus of (6), wherein the impedance adjustment mechanism includes:
a first impedance adjustment mechanism controlling the first bias signal,
an isolator connected between the impedance adjustment electrode and the first impedance adjustment mechanism and blocking the second bias signal, and
a second impedance adjustment mechanism controlling the second bias signal, and
wherein the isolator and the first impedance adjustment mechanism are connected in parallel with the second impedance adjustment mechanism.
   (8)

The plasma processing apparatus of (7), wherein the first impedance adjustment mechanism is configured to include at least one of a variable resistor, a variable capacitor, and a variable inductor, and
the second impedance adjustment mechanism is configured to include at least one of a variable resistor, a variable capacitor, and a variable inductor.
   (9)

The plasma processing apparatus of any one of (1) to (8), wherein a frequency of the first bias signal is lower than a frequency of the second bias signal.

(10)

The plasma processing apparatus of any one of (1) to (9), wherein the impedance adjustment mechanism is adjusted from low impedance to high impedance in response to an increase in erosion amount of the edge ring.

(11)

The plasma processing apparatus of any one of (1) to (10), wherein the impedance adjustment mechanism is connected to the impedance adjustment electrode through a conductive bar,
the conductive bar is arranged along an inner peripheral side of the second region, and includes a first connection portion connected to the impedance adjustment mechanism and a second connection portion connected to the impedance adjustment electrode, and
the first connection portion and the second connection portion are adjacent to each other in a circumferential direction with an unconnected portion in the circumferential direction between the first connection portion and the second connection portion.
   (12)

The plasma processing apparatus of (11), wherein the conductive bar is disposed below a base of the substrate support, and functions as a split ring resonator.

(13)

The plasma processing apparatus of (12), wherein a resonant frequency of the split ring resonator is a frequency of the second bias signal.

(14)

The plasma processing apparatus of any one of (1) to (10), wherein the impedance adjustment mechanism is connected to a plurality of the impedance adjustment electrodes through a conductive bar,
the conductive bar includes a first conductive bar arranged in a circumferential direction along an inner peripheral side of the second region, and a plurality of second conductive bars arranged from the first conductive bar toward a center of a base of the substrate support,
each of the plurality of second conductive bars has a first connection portion connected to the impedance adjustment mechanism, and
the first conductive bar has a plurality of second connection portions connected to a plurality of the impedance adjustment electrodes at connection portions connected to the plurality of second conductive bars.
   (15)

The plasma processing apparatus of any one of (1) to (10), wherein the impedance adjustment mechanism is connected to the impedance adjustment electrode through a conductive bar, and
the conductive bar is arranged along the second region to have multiple turns.
   (16)

The plasma processing apparatus of any one of (1) to (15), further comprising:
a measurement section configured to measure a voltage and a current of a bias RF signal output from at least one of the first bias power source and the second bias power source,
wherein the bias power source is configured to control power of the bias RF signal such that a potential of the first bias electrode and the second bias electrode becomes a preset setting value, based on the voltage and the current which are measured by the measurement section when the impedance adjustment mechanism is adjusted.
   (17)

The plasma processing apparatus of any one of (1) to (15), further comprising:
a measurement section configured to measure a voltage and a current of a bias DC signal output from at least one of the first bias power source and the second bias power source,
wherein the bias power source is configured to control power of the bias DC signal such that power supplied to the first bias electrode and the second bias electrode becomes a preset setting value, based on the voltage and the current which are measured in the measurement section when the impedance adjustment mechanism is adjusted.

1. A plasma processing apparatus comprising:
a chamber;
a first bias power source configured to supply a first bias signal;
a second bias power source configured to supply a second bias signal;
a substrate supporter for supporting a substrate and an edge ring, inside the chamber;
an impedance adjustment mechanism; and
an electrical path,
wherein the substrate supporter is configured to include:
a first region supporting the substrate,
a second region provided around the first region and supporting the edge ring,
a first bias electrode provided in the first region,
a second bias electrode provided in the second region, and
an impedance adjustment electrode provided in the second region and grounded, and
wherein the impedance adjustment mechanism includes:
a first impedance adjustment mechanism controlling the first bias signal,
an isolator connected between the impedance adjustment electrode and the first impedance adjustment mechanism and blocking the second bias signal, and
a second impedance adjustment mechanism controlling the second bias signal,
wherein the isolator and the first impedance adjustment mechanism, and the second impedance adjustment mechanism are connected in parallel, and are configured to be connected to the impedance adjustment electrode, and
the electrical path is configured to connect the first bias power source and the second bias power source, to the first bias electrode and the second bias electrode.

2. The plasma processing apparatus of claim 1, wherein the electrical path is provided with a switch between the first bias power source and the second bias power source, and the second bias electrode,
the switch is controlled to be turned on when the first bias signal is supplied, and the switch is controlled to be turned off when the second bias signal is supplied.

3. The plasma processing apparatus of claim 1, wherein the first impedance adjustment mechanism is configured to include at least one of a variable resistor, a variable capacitor, and a variable inductor, and
the second impedance adjustment mechanism is configured to include at least one of the variable resistor, the variable capacitor, and the variable inductor.

4. The plasma processing apparatus of claim 3, wherein a frequency of the first bias signal is lower than a frequency of the second bias signal,
the first impedance adjustment mechanism is configured to include a first variable capacitor,
the second impedance adjustment mechanism is configured to include a second variable capacitor, and
a variable range of capacitance of the first variable capacitor is larger than a variable range of capacitance of the second variable capacitor.

5. The plasma processing apparatus of claim 1, wherein the isolator includes a resonant circuit having a resonant frequency that is a frequency of the second bias signal.

6. A plasma processing apparatus comprising:
a chamber;
a first bias power source configured to supply a first bias signal;
a second bias power source configured to supply a second bias signal;
a substrate supporter for supporting a substrate and an edge ring, inside the chamber;
an impedance adjustment mechanism; and
an electrical path,
wherein the substrate supporter is configured to include:
a first region supporting the substrate,
a second region provided around the first region and supporting the edge ring,
a first bias electrode provided in the first region,
a second bias electrode provided in the second region, and
an impedance adjustment electrode provided in the second region and grounded, and
wherein the impedance adjustment mechanism is configured to be connected to the impedance adjustment electrode, and
the electrical path is configured to connect the first bias power source and the second bias power source, to the first bias electrode and the second bias electrode, and
a switch is provided between the first bias power source and the second bias power source, and the second bias electrode, and
the switch is controlled to be turned on when the first bias signal is supplied, and the switch is controlled to be turned off when the second bias signal is supplied.

7. The plasma processing apparatus of claim 6, wherein the impedance adjustment mechanism includes:
a first impedance adjustment mechanism controlling the first bias signal,
an isolator connected between the impedance adjustment electrode and the first impedance adjustment mechanism and blocking the second bias signal, and
a second impedance adjustment mechanism controlling the second bias signal, and
wherein the isolator and the first impedance adjustment mechanism are connected in parallel with the second impedance adjustment mechanism.

8. The plasma processing apparatus of claim 7, wherein the first impedance adjustment mechanism is configured to include at least one of a variable resistor, a variable capacitor, and a variable inductor, and
the second impedance adjustment mechanism is configured to include at least one of a variable resistor, a variable capacitor, and a variable inductor.

9. The plasma processing apparatus of claim 1, wherein a frequency of the first bias signal is lower than a frequency of the second bias signal.

10. The plasma processing apparatus of claim 1, wherein the impedance adjustment mechanism is adjusted from low impedance to high impedance in response to an increase in erosion amount of the edge ring.

11. The plasma processing apparatus of claim 1, wherein the impedance adjustment mechanism is connected to the impedance adjustment electrode through a conductive bar,
the conductive bar is arranged along an inner peripheral side of the second region, and includes a first connection portion connected to the impedance adjustment mechanism and a second connection portion connected to the impedance adjustment electrode, and
the first connection portion and the second connection portion are adjacent to each other in a circumferential direction with an unconnected portion in the circumferential direction between the first connection portion and the second connection portion.

12. The plasma processing apparatus of claim 11, wherein the conductive bar is disposed below a base of the substrate support, and functions as a split ring resonator.

13. The plasma processing apparatus of claim 12, wherein a resonant frequency of the split ring resonator is a frequency of the second bias signal.

14. The plasma processing apparatus of claim 1, wherein the impedance adjustment mechanism is connected to a plurality of the impedance adjustment electrodes through a conductive bar,
the conductive bar includes a first conductive bar arranged in a circumferential direction along an inner peripheral side of the second region, and a plurality of second conductive bars arranged from the first conductive bar toward a center of a base of the substrate support,
each of the plurality of second conductive bars has a first connection portion connected to the impedance adjustment mechanism, and
the first conductive bar has a plurality of second connection portions connected to a plurality of the impedance adjustment electrodes at connection portions connected to the plurality of second conductive bars.

15. The plasma processing apparatus of claim 1, wherein the impedance adjustment mechanism is connected to the impedance adjustment electrode through a conductive bar, and
the conductive bar is arranged along the second region to have multiple turns.

16. The plasma processing apparatus of claim 1, further comprising:
a measurement section configured to measure a voltage and a current of a bias RF signal output from at least one of the first bias power source and the second bias power source,
wherein the bias power source is configured to control power of the bias RF signal such that a potential of the first bias electrode and the second bias electrode becomes a preset setting value, based on the voltage and the current which are measured by the measurement section when the impedance adjustment mechanism is adjusted.

17. The plasma processing apparatus of claim 1, further comprising:
a measurement section configured to measure a voltage and a current of a bias DC signal output from at least one of the first bias power source and the second bias power source,
wherein the bias power source is configured to control power of the bias DC signal such that power supplied to the first bias electrode and the second bias electrode becomes a preset setting value, based on the voltage and the current which are measured in the measurement section when the impedance adjustment mechanism is adjusted.

18. The plasma processing apparatus of claim 6, wherein a frequency of the first bias signal is lower than a frequency of the second bias signal.

19. The plasma processing apparatus of claim 6, wherein the impedance adjustment mechanism is adjusted from low impedance to high impedance in response to an increase in erosion amount of the edge ring.

20. The plasma processing apparatus of claim 6, wherein the impedance adjustment mechanism is connected to the impedance adjustment electrode through a conductive bar,
the conductive bar is arranged along an inner peripheral side of the second region, and includes a first connection portion connected to the impedance adjustment mechanism and a second connection portion connected to the impedance adjustment electrode, and
the first connection portion and the second connection portion are adjacent to each other in a circumferential direction with an unconnected portion in the circumferential direction between the first connection portion and the second connection portion.

21. The plasma processing apparatus of claim 6, wherein the impedance adjustment mechanism is connected to a plurality of the impedance adjustment electrodes through a conductive bar,
the conductive bar includes a first conductive bar arranged in a circumferential direction along an inner peripheral side of the second region, and a plurality of second conductive bars arranged from the first conductive bar toward a center of a base of the substrate support,
each of the plurality of second conductive bars has a first connection portion connected to the impedance adjustment mechanism, and
the first conductive bar has a plurality of second connection portions connected to a plurality of the impedance adjustment electrodes at connection portions connected to the plurality of second conductive bars.

22. The plasma processing apparatus of claim 6, wherein the impedance adjustment mechanism is connected to the impedance adjustment electrode through a conductive bar, and
the conductive bar is arranged along the second region to have multiple turns.

23. The plasma processing apparatus of claim 6, further comprising:
a measurement section configured to measure a voltage and a current of a bias RF signal output from at least one of the first bias power source and the second bias power source,
wherein the bias power source is configured to control power of the bias RF signal such that a potential of the first bias electrode and the second bias electrode becomes a preset setting value, based on the voltage and the current which are measured by the measurement section when the impedance adjustment mechanism is adjusted.

24. The plasma processing apparatus of claim 6, further comprising:
a measurement section configured to measure a voltage and a current of a bias DC signal output from at least one of the first bias power source and the second bias power source,
wherein the bias power source is configured to control power of the bias DC signal such that power supplied to the first bias electrode and the second bias electrode becomes a preset setting value, based on the voltage and the current which are measured in the measurement section when the impedance adjustment mechanism is adjusted.
